(19) United States
(12) Patent Application Publication
(10) Pub. No.: US 2026/0333868 A1
(43) Pub. Date: Oct. 22, 2026

(54) SEMICONDUCTOR STRUCTURES AND METHODS OF FORMING THE SAME

(71) Applicant: TAIWAN SEMICONDUCTOR MANUFACTURING COMPANY LTD., HSINCHU (TW)

(72) Inventors: YONG-JIE WU, TAINAN CITY (TW); YEN-CHUNG HO, HSINCHU (TW); KATHERINE H. CHIANG, NEW TAIPEI CITY (TW)

(21) Appl. No.: 19/181,385

(22) Filed: Apr. 17, 2025

(51) Int. Cl. H10D 86/40; H10D 30/01; H10D 30/67; H10D 86/01

(52) U.S. Cl. CPC H10D 86/441; H10D 30/0312; H10D 30/6735; H10D 86/0221

(57) ABSTRACT

A method of forming a semiconductor structure includes forming a transistor having active regions in a substrate, and forming a memory structure over the substrate and above the transistor. The method of forming the memory structure includes forming a first gate electrode over the substrate and above the transistor, forming a first gate dielectric layer on the first gate electrode, and forming a channel layer on the first gate dielectric layer. The method further includes forming a second gate dielectric layer on the first gate dielectric layer and covering the channel layer; and forming a second gate electrode on the second gate dielectric layer and around three sides of the channel layer. The method further includes forming source/drain features on the second gate dielectric layer and in lateral contact with opposite ends of the channel layer, and then forming a memory cell on one of the source/drain features.

### BACKGROUND

In the semiconductor industry, there is a constant desire to increase the integration density of integrated circuits. To do so, individual elements or components have become increasingly smaller. In addition, moving peripheral transistors from the front-end-of-line (FEOL) to the back-end-of-line (BEOL) of fabrication may be advantageous because functionality may be added at the BEOL while valuable chip area may be made available in the FEOL. Transistors such as thin film transistors (TFTs) are considered promising candidates for BEOL control elements in memory devices. A TFT structure that has a channel layer made of oxide semiconductor can be scaled down for the application of high-density memory arrays.

Although the scaling-down process generally provides benefits by increasing production efficiency and lowering associated costs, such scaling down has also increased the complexity of manufacturing semiconductor devices, and may have considerable effects on the electrical performance of the devices. For example, the scaling-down of memory devices with transistors having oxide semiconductor channels suffers from serious short-channel effects (SCEs). Thus, although existing semiconductor devices have generally been adequate for their intended purposes, as device scaling down continues, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view of an exemplary semiconductor structure prior to formation of an array of memory structures, in accordance with some embodiments of the present disclosure.

FIG. 2 is a cross-sectional view of an exemplary semiconductor structure during formation of an array of memory structures, in accordance with some embodiments of the present disclosure.

FIG. 3 is a cross-sectional view of an exemplary semiconductor structure after the formation of upper-level metal interconnect structures.

FIGS. 4A, 5A, 6A, 7A, 8A, 9A, 10A, 11A, 12A, 13A, 14A, and 15A are fragmentary perspective views illustrating a method of forming a memory structure at various intermediate stages, in accordance with some embodiments of the present disclosure.

FIGS. 4B, 5B, 6B, 7B, 8B, 9B, 10B, 11B, 12B, 13B, 14B, and 15B are cross-sectional views of various intermediate stages of forming a memory structure taken along cross-section B-B in FIGS. 4A, 5A, 6A, 7A, 8A, 9A, 10A, 11A, 12A, 13A, 14A, and 15A, respectively.

FIGS. 4C, 5C, 6C, 7C, 8C, 9C, 10C, 11C, 12C, 13C, 14C, and 15C are cross-sectional views of various intermediate stages of forming a memory structure taken along cross-section C-C in FIGS. 4A, 5A, 6A, 7A, 8A, 9A, 10A, 11A, 12A, 13A, 14A, and 15A, respectively.

FIG. 16 is a flowchart illustrating a method 1600 for forming a memory structure, in accordance with some embodiments of the present disclosure.

FIG. 17 is a cross-sectional view of an exemplary semiconductor structure with upper-level metal interconnect structures, including an array of memory structures, in accordance with some embodiments of the present disclosure.

FIG. 18 illustrates a portion of an array of memory structures, in accordance with some embodiments of the present disclosure.

FIG. 19 illustrates a portion of an array of memory structures, in accordance with some embodiments of the present disclosure.

FIG. 20 illustrates a portion of an array of memory structures, in accordance with some embodiments of the present disclosure.

FIGS. 21-24 are top views each depicting a transistor of a memory structure, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context. In addition, a source/drain feature as used herein may refer to a source or a drain, individually or collectively dependent upon the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the like thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure is generally related to semiconductor structures including memory structures and methods of forming the same. Each of the memory structures may include a transistor (such as a TFT) and a memory cell formed on and coupled to the transistor. In some embodiments, the transistor includes a GAA-like gate electrode structure to improve gate control. For example, a channel layer is surrounded by a gate structure having two gate dielectric layers and two gate electrodes. A top gate electrode and a bottom gate electrode may be disposed on opposite sides of a channel layer, and the top gate electrode may extend across at least three sides of the channel layer. In some embodiments, the gate electrode structure enhances the gate control behavior, thereby improving the electrical performances of the transistor, such as reducing short-channel effects (SCEs) and reducing OFF-state current. In some embodiments where transistors having oxide semiconductor channels continue scaling down to shrink the gate length and channel length, the transistors suppress short-channel effects (SCEs), and the leakage current on back channel can be reduced as well. In addition, in some embodiments, the methods of forming the semiconductor structures provide a simple process to form a GAA-like gate electrode structure instead of using complex GAA (gate-all-around) processes.

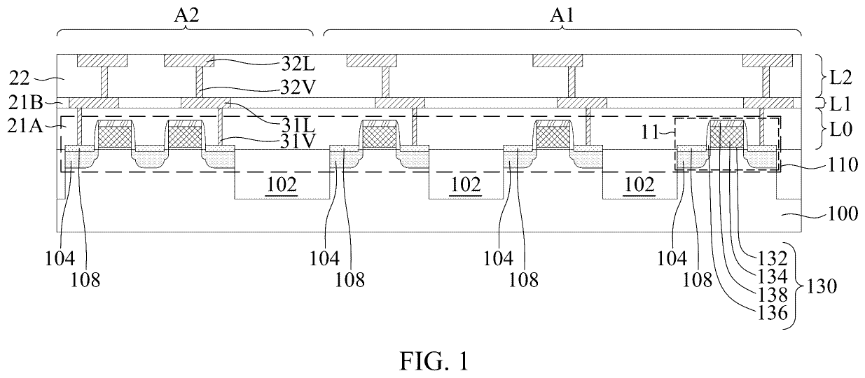

The various aspects of the present disclosure will now be described in more detail with reference to the figures. FIG. 1 is a cross-sectional view of an exemplary semiconductor structure prior to formation of an array of memory structures, in accordance with some embodiments of the present disclosure.

The exemplary semiconductor structure includes a substrate 100. The substrate 100 may include a bulk semiconductor substrate such as a silicon substrate in which the semiconductor material layer continuously extends from a top surface of the substrate 100 to a bottom surface of the substrate 100, or a semiconductor-on-insulator layer, including the semiconductor material layer as a top semiconductor layer overlying a buried insulator layer (such as a silicon oxide layer). The exemplary semiconductor structure may include various device regions, which may include a memory array region A1 in which at least one array of non-volatile memory cells or volatile memory cells may be subsequently formed. The exemplary semiconductor structure may also include a peripheral logic region A2 in which electrical connections between each array of memory cells and a peripheral circuit including field-effect transistors may be subsequently formed. Areas of the memory array region A1 and the peripheral logic region A2 may be employed to form various elements of the peripheral circuit.

Semiconductor devices such as field-effect transistors (FETs) may be formed on and/or in the semiconductor material layer during a front-end-of-line (FEOL) fabrication process. For example, shallow trench isolation structures 102 may be formed in an upper portion of the semiconductor material layer of the substrate 100 by forming shallow trenches and subsequently filling the shallow trenches with a dielectric material such as silicon oxide. Other suitable dielectric materials are within the scope of disclosure. Various doped wells (not expressly shown) may be formed in various regions of the upper portion of the semiconductor material layer by performing masked ion implantation processes.

In some embodiments, gate structures 130 are formed over the top surface of the substrate 100 by depositing and patterning a gate dielectric layer, a gate electrode layer, and a gate cap dielectric layer. Each of the gate structures 130 may include a vertical stack of a gate dielectric 132, a gate electrode 134, and a gate cap dielectric 138, which is herein referred to as a gate stack (132, 134, 138). Ion implantation processes may be performed to form extension implant regions, which include source extension regions and drain extension regions. Gate spacers 136 may be formed on the sidewalls of the gate stacks (132, 134, 138). A gate stack (132, 134, 138) and a gate spacer 136 together constitute a gate structure 130. Additional ion implantation processes may be performed that use the gate structures 130 as self-aligned implantation masks to form active regions. Such active regions may include source regions and drain regions. The upper portions of the active regions may overlap with portions of the extension implantation regions. Each combination of an extension implantation region and an active region may constitute an active region 104, which may be a source region or a drain region depending on electrical biasing. A semiconductor channel 105 may be formed underneath each of the gate stacks (132, 134, 138) between a neighboring pair of active regions 104. Metal-semiconductor alloy regions 108 may be formed on the top surfaces of the active regions 104.

In embodiments where an array of memory structures may subsequently be formed at a level of a dielectric layer (e.g., a third interconnect dielectric layer 23 described later) on a FEOL structure, field-effect transistors (FET) 11 may be formed on the semiconductor material layer and may include a circuit that provides functions to operate memory cells of the memory structures. Additionally, devices in the peripheral logic region A2 may be configured to control the programming, erase, and sensing (read) operation of the memory cells. For example, the devices in the peripheral logic region A2 may include sensing and/or programming circuitry. Complementary metal-oxide-semiconductor (CMOS) transistors may be provided on the semiconductor material layer, which may include a peripheral circuit for the array(s) of TFTs to be subsequently formed. CMOS transistors and optionally additional semiconductor devices (such as resistors, diodes, capacitors, etc.) are collectively referred to as CMOS circuitry 110.

One or more of the field-effect transistors 11 in the CMOS circuitry 110 may be formed on the semiconductor material layer. Each of the field-effect transistors 11 may include a gate structure 130, a semiconductor channel 105, a pair of active regions 104 (one of which functions as a source region and another of which functions as a drain region), and optional metal-semiconductor alloy regions 108. In some embodiments, several field-effect transistors 11 in the CMOS circuitry 110 may include a respective node that is subsequently electrically connected to a node of a respective memory cell to be subsequently formed. For example, one of the field-effect transistors 11 in the CMOS circuitry 110 includes active regions 104. One of these active regions 104 functions as either a source electrode or a drain electrode, which is electrically connected to a node of a respective memory cell formed subsequently.

Various interconnect-level structures may be subsequently formed, which are created prior to formation of an array of memory structures, and are herein referred to as lower interconnect-level structures (L0, L1, L2). Structures (e.g., FETs) on the substrate 100 and the lower interconnect-level structures (L0, L1, L2) can be referred to as a FEOL structure. In the case that a two-dimensional array of the memory structures is to be subsequently formed over two levels of interconnect-level metal lines, the lower interconnect-level structures (L0, L1, L2) may include a contact-level structure L0, a first interconnect-level structure L1, and a second interconnect-level structure L2.

The contact-level structure L0 may include a planarization dielectric layer 21A including a planarizable dielectric material such as silicon oxide and various contact via structures 31V contacting a respective one of the active regions 104 or the gate electrodes 134 and formed within the planarization dielectric layer 21A. The first interconnect-level structure L1 includes a first interconnect dielectric layer 21B and first metal lines 31L formed within the first interconnect dielectric layer 21B. The first interconnect dielectric layer 21B is also referred to as a first line-level dielectric layer. The first metal lines 31L may contact a respective one of the contact via structures 31V. The second interconnect-level structure L2 includes a second interconnect dielectric layer 22, which may include a stack of a first via-level dielectric material layer and a second line-level dielectric material layer or a line-and-via-level dielectric material layer. The second interconnect dielectric layer 22 may have formed in second interconnect-level metal interconnect structures (32V, 32L), which include first metal via structures 32V and second metal lines 32L. Top surfaces of the second metal lines 32L may be coplanar with the top surface of the second interconnect dielectric layer 22.

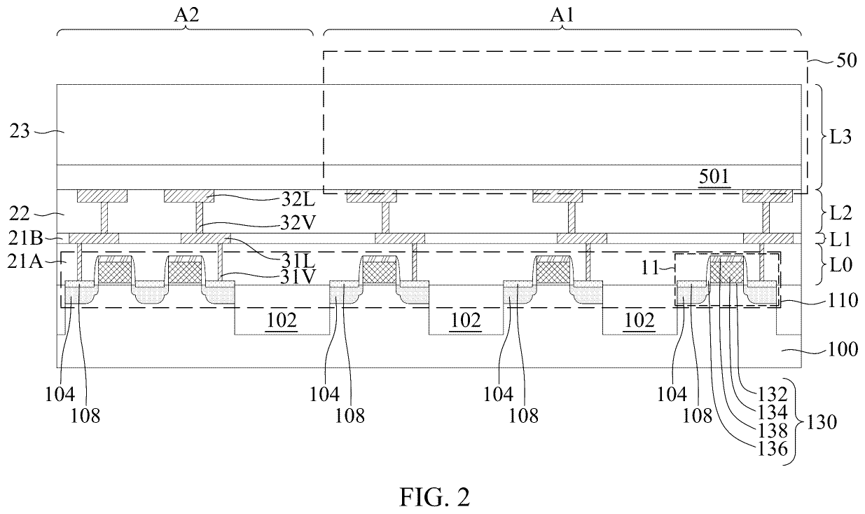

FIG. 2 is a cross-sectional view of an exemplary semiconductor structure during formation of an array of memory structures, in accordance with some embodiments of the present disclosure. In some embodiments, an array 50 of memory structures is formed in the memory array region A1 over the second interconnect-level structure L2. Each of the memory structures may include a thin-fin transistor (TFT) (such as a back gate TFT selector or any type of selector device) and a memory cell on the TFT. The details of the structures and the processing steps for the array 50 of memory structures are described in detail below. A third interconnect dielectric layer 23 may be formed during formation of the array 50 of memory structures. The set of all structures formed at the level of the transistors of the array 50 of memory structures is herein referred to as a third interconnect-level structure L3. The memory cells on the TFTs may be formed in a next level, and may be parts of a fourth interconnect-level structure L4.

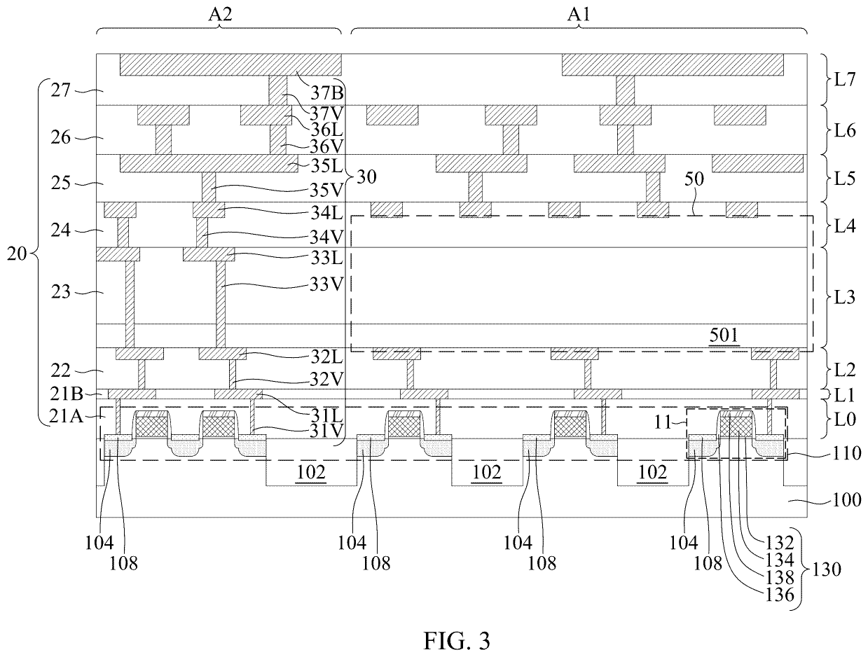

FIG. 3 is a cross-sectional view of an exemplary semiconductor structure after the formation of upper-level metal interconnect structures. Referring to FIG. 3, third interconnect-level metal interconnect structures (33V, 33L) may be formed in the third interconnect dielectric layer 23. The third interconnect-level metal interconnect structures (33V, 33L) may include second metal via structures 33V and third metal lines 33L. In some embodiments, additional interconnect-level structures are subsequently formed, which are herein referred to as upper interconnect-level structures (L4, L5, L6, L7). For example, the upper interconnect-level structures (L4, L5, L6, L7) may include a fourth interconnect-level structure L4, a fifth interconnect-level structure L5, a sixth interconnect-level structure L6, and a seventh interconnect-level structure L7. The fourth interconnect-level structure L4 may include a fourth interconnect dielectric layer 24 having formed therein fourth interconnect-level metal interconnect structures (34V, 34L), which may include third metal via structures 34V and fourth metal lines 34L. The fifth interconnect-level structure L5 may include a fifth interconnect dielectric layer 25 having formed therein fifth interconnect-level metal interconnect structures (35V, 35L), which may include fourth metal via structures 35V and fifth metal lines 35L. The sixth interconnect-level structure L6 may include a sixth interconnect dielectric layer 26 having formed therein sixth interconnect-level metal interconnect structures (36V, 36L), which may include fifth metal via structures 36V and sixth metal lines 36L. The seventh interconnect-level structure L7 may include a seventh interconnect dielectric layer 27 having formed therein sixth metal via structures 37V (which are seventh interconnect-level metal interconnect structures) and metal bonding pads 37B. The metal bonding pads 37B may be configured for solder bonding (which may employ C4 ball bonding or wire bonding), or may be configured for metal-to-metal bonding (such as copper-to-copper bonding). It should be noted that although four interconnect-level structures (L4, L5, L6, L7) are formed over an array of TFTs in this exemplified embodiment, the disclosure is not limited thereto. An interconnect structure that includes other numbers of interconnect-level structures can be formed above the TFTs.

Each interconnect dielectric layer may be referred to as an interconnect dielectric layer (ILD) layer 20. Each interconnect-level metal interconnect structure may be referred to as a metal interconnect structure 30. Each contiguous combination of a metal via structure and an overlying metal line located within a same interconnect-level structure (L2-L7) may be formed sequentially as two distinct structures by employing two single damascene processes, or may be simultaneously formed as a unitary structure employing a dual damascene process. Each of the metal interconnect structures 30 may include a respective metallic liner (such as a layer of TiN, TaN, or WN having a thickness in a range from 2 nm to 20 nm) and a respective metallic fill material (such as W, Cu, Co, Mo, Ru, another elemental metal, or an alloy or a combination thereof). Other suitable materials for use as a metallic liner and metallic fill material are within the contemplated scope of disclosure. Various etch stop dielectric layers and dielectric capping layers may be inserted between vertically neighboring pairs of ILD layers 20, or may be incorporated into one or more of the ILD layers 20.

While the present disclosure is described employing an embodiment in which the transistors of the array 50 of memory structures are formed as components of a third interconnect-level structure L3, embodiments are expressly contemplated herein in which the transistors of the array 50 of memory structures may be formed as components of any other interconnect-level structure (e.g., L1-L7). Further, while the present disclosure is described using an embodiment in which a set of eight interconnect-level structures is formed, embodiments are expressly contemplated herein in which a different number of interconnect-level structures is used. In addition, embodiments are expressly contemplated herein in which two or more arrays 50 of memory structures may be provided within multiple interconnect-level structures in the memory array region A1. While the present disclosure is described employing an embodiment in which an array 50 of memory structures is formed over two vertically adjoining interconnect-level structures, embodiments are expressly contemplated herein in which an array 50 of memory structures may be formed in a single interconnect-level structure.

In some embodiments, an array 50 of memory structures includes several memory structures. Each of the memory structures may include a transistor (such as a thin-fin transistor (TFT)) and a memory cell on the transistor. The transistor may act as a selector for the memory cell formed thereon. In some embodiments, the transistors of two memory structures of the array 50 have different structural configurations which are suitable for the memory cells with different threshold voltages. According to the method of the embodiments, the transistors of the array 50 of memory structures can be formed in the same interconnect-level structure, such as in the third interconnect-level structure L3, or in any other interconnect-level structure (e.g., L1-L7). The memory cells formed on the transistors may be formed in an interconnect-level structure (e.g., L4) adjacent to the interconnect-level structure (e.g., L3) in which the transistors of the embodiments are formed.

Thus, according to the embodiments, the transistors serving as selectors for the memory cells are moved from a FEOL structure to a BEOL structure, which provides several advantages for BEOL integration. For example, transistors such as TFTs may be processed at low temperature and can add functionality to the BEOL structure, while valuable chip area is made available in the FEOL structure. The Use of TFTs in the BEOL structure may serve as a scaling path for 3 nm node fabrication (N3) or beyond by relocating peripheral devices, such as power gates or Input/Output (I/O) devices, from the FEOL structure into higher metal levels of the BEOL structure. Relocating the TFTs from the FEOL structure to the BEOL structure may result in an area reduction of approximately 5% to 10% for a given device.

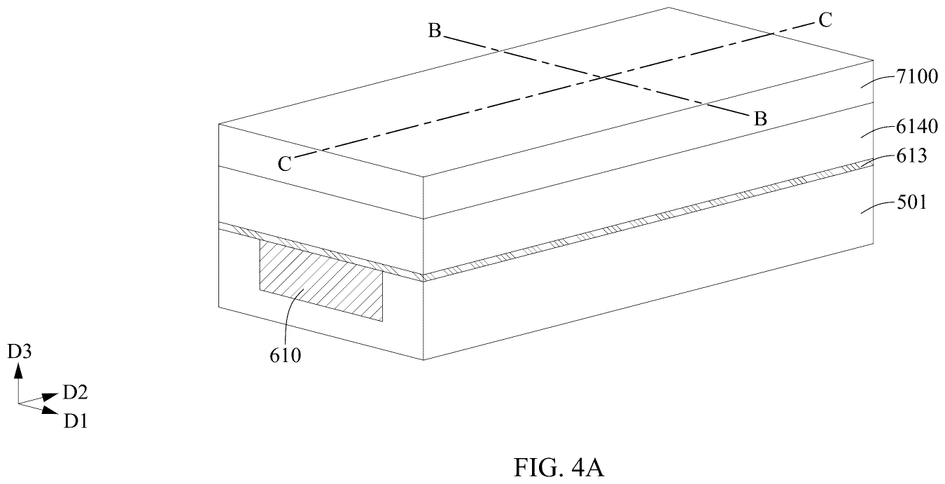

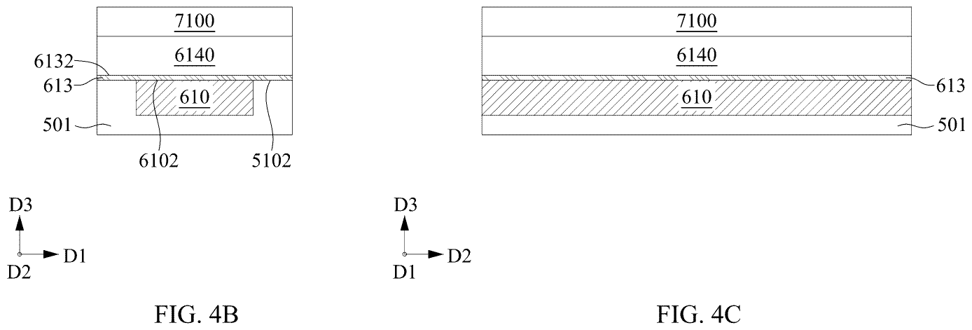

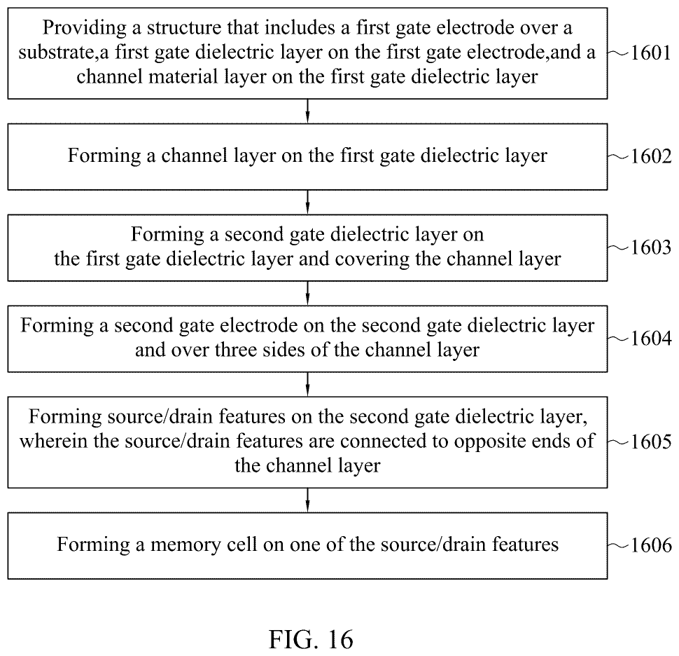

FIGS. 4A, 5A, 6A, 7A, 8A, 9A, 10A, 11A, 12A, 13A, 14A, and 15A are fragmentary perspective views illustrating a method of forming a memory structure at various intermediate stages, in accordance with some embodiments of the present disclosure. FIGS. 4B, 5B, 6B, 7B, 8B, 9B, 10B, 11B, 12B, 13B, 14B, and 15B are cross-sectional views of various intermediate stages of forming a memory structure taken along cross-section B-B in FIGS. 4A, 5A, 6A, 7A, 8A, 9A, 10A, 11A, 12A, 13A, 14A, and 15A, respectively. FIGS. 4C, 5C, 6C, 7C, 8C, 9C, 10C, 11C, 12C, 13C, 14C, and 15C are cross-sectional views of various intermediate stages of forming a memory structure taken along cross-section C-C in FIGS. 4A, 5A, 6A, 7A, 8A, 9A, 10A, 11A, 12A, 13A, 14A, and 15A, respectively. FIG. 16 is a flowchart illustrating a method 1600 for forming a memory structure, in accordance with some embodiments of the present disclosure.

Method 1600 is merely an example and is not intended to limit the present disclosure to what is explicitly illustrated in method 1600. Additional steps can be provided before, during, and after method 1600, and some steps described can be replaced, eliminated, or rearranged for additional embodiments of the method. Not all steps are described in detail herein for reasons of simplicity. In addition, the directions D1, D2 and D3 in FIGS. 4A-15A, 4B-15B and 4C-15C are perpendicular to one another. Throughout the present disclosure, like reference numerals denote like features, unless otherwise specified.

Referring to FIGS. 4A, 4B, 4C and 16, method 1600 includes a block 1601 where a structure that includes a first gate electrode 610 over a substrate (e.g., the substrate 100 in FIGS. 1-3), a first gate dielectric layer 613 over the first gate electrode 610, and a channel material layer 6140 on the first gate dielectric layer 613 is provided.

In some embodiments, an insulating material layer 501 is formed over the substrate. The insulating material layer 501 may include a dielectric material such as silicon oxide (SiO₂), undoped silicate glass, a doped silicate glass, organosilicate glass, amorphous fluorinated carbon, porous variants thereof, or combinations thereof. The insulating material layer 501 may be deposited through any of a number of suitable deposition processes or grown over an interconnect-level structure, such as the second interconnect-level structure L2 or any other interconnect-level structure.

In some embodiments, the first gate electrode 610 is formed in the insulating material layer 501. The top surface 6102 of the first gate electrode 610 is substantially coplanar with the top surface 5012 of the insulating material layer 501. The formation of the first gate electrode 610 may include forming a gate trench in the insulating material layer 501, depositing at least one conductive material on the insulating material layer 501 and within the gate trench, and removing excess amounts of the at least one conductive material over the top surface 5012 of the insulating material layer 501. The at least one conductive material may include, for example, a metallic barrier liner material (not shown) (such as TiN, TaN, WN, or any suitable barrier material) and a metallic fill material. In some embodiments, the metallic fill material of the first gate electrode 610 includes copper, aluminum, zirconium, titanium, tungsten, tantalum, tantalum nitride, ruthenium, palladium, platinum, cobalt, nickel, iridium, alloys thereof, another suitable metallic fill material, or a combination thereof. Other suitable metallic liner and metallic fill materials within the contemplated scope of disclosure may also be used.

One or more conductive materials of the first gate electrode 610 may be deposited by a chemical vapor deposition (CVD) process, a physical vapor deposition (PVD) process, an atomic layer deposition (ALD) process, a sputtering process, laser ablation, or any suitable process. The CVD process may include a high density plasma CVD (HDPCVD) process, a metalorganic CVD (MOCVD) process, a plasma enhanced CVD (PECVD) process, or any suitable method.

A planarization process, such as a chemical mechanical polishing (CMP) process or the like, may then be performed to remove excess portions of the conductive material above the top surface 5012 of the insulating material layer 501. After planarization, the top surface 5012 of the insulating material layer 501 is exposed and coplanar with the top surface 6102 of the first gate electrode 610.

In some embodiments, after the first gate electrode 610 is formed, the first gate dielectric layer 613 is formed to extend continuously with a substantially constant thickness from the top surface 5012 of the insulating material layer 501 to the top surface 6102 of the first gate electrode 610. In some embodiments, the first gate dielectric layer 613 is a high-k dielectric layer, and can be formed by depositing any suitable high-k dielectric material using any suitable deposition process. The high-k dielectric layer may have a dielectric constant greater than 3.9.

The first gate dielectric layer 613 may include, but are not limited to, silicon nitride, hafnium oxide (HfO₂), hafnium silicon oxide (HfSiO), hafnium tantalum oxide (HfTaO), hafnium titanium oxide (HfTiO), hafnium zirconium oxide (Hf_{0.5}Zr_{0.5}O₂) (HZO), tantalum oxide (Ta₂O₅), aluminum oxide (Al₂O₃), hafnium dioxide-alumina (HfO₂—Al₂O₃), zirconium oxide (ZrO₂), titanium oxide (TiO₂), strontium titanium oxide (SrTiO₃), or another suitable high-k dielectric material. Other suitable dielectric materials are within the scope of the present disclosure. In addition, the first gate dielectric layer 613 may have a thickness in the range of 0.5 nm to 5.0 nm, such as 1 nm to 4 nm, although greater or lesser thicknesses may also be used. In some embodiments, the first gate dielectric layer 613 is formed by ALD, and has a thickness measured in direction D3, ranging between 1 nm and 3 nm. These numerical values are provided for exemplification purposes only and are not intended to be limiting.

In some embodiments, after the first gate dielectric layer 613 is formed, a channel material layer 6140 is formed on the first gate dielectric layer 613 and extends continuously with a substantially uniform thickness Tc (e.g., measured in direction D3) from the top surface 6132 of the first gate dielectric layer 613. As shown in FIGS. 4A, 4B and 4C, in some embodiments, the channel material layer 6140 is separated from the first gate electrode 610 by the first gate dielectric layer 613. In some embodiments, the thickness Tc of the channel material layer 6140 is between about 50 angstroms and about 100 angstroms. These numerical values are provided for exemplification purposes only and are not intended to be limiting.

The channel material layer 6140 may be formed by depositing any suitable semiconductor material, using any suitable deposition process. In some embodiments, the channel material layer 6140 includes polysilicon, amorphous silicon, or a semiconducting oxide, such as InGaZnO (IGZO), indium tin oxide (ITO), InWO, InZnO, InSnO, GaOx, InOx, or the like. Other suitable semiconductor materials are within the scope of the present disclosure.

Next, in some embodiments, a mask layer 7100 is deposited over the channel material layer 6140. The mask layer 7100 may have a single-layered structure, or a multi-layered structure including two or more layers stacked from bottom to top. The mask layer 7100 may include one or more hard mask (HM) layers and a photoresist layer on the one or more hard mask (HM) layers. The hard mask (HM) layers may be made of any suitable material, such as amorphous carbon, organo-siloxane-based materials, TiN, SiN, SiON, SiO₂, or combinations thereof. Other suitable materials are within the contemplated scope of disclosure. The mask layer 7100 may be formed using chemical vapor deposition (CVD), physical vapor deposition (PVD), atomic layer deposition (ALD) or any other suitable process. For the sake of simplicity and clarity, a mask layer 7100 that has a single-layered structure is depicted in the drawings.

In some embodiments where an IGZO pillar is formed as a channel layer 614 and a TiN hard mask is adopted to pattern the IGZO pillar, the TiN hard mask can be removed by logic-compatible TRC process, which shows high selectivity of TiN. The channel layer 614 formed of the high-k material (e.g., the dielectric constant of IGZO is about 9) has benefit of preventing channel material loss during removal of the TiN hard mask. However, the disclosure is not limited thereto. Other suitable materials for forming the channel layer and the hard mask may be implemented herein.

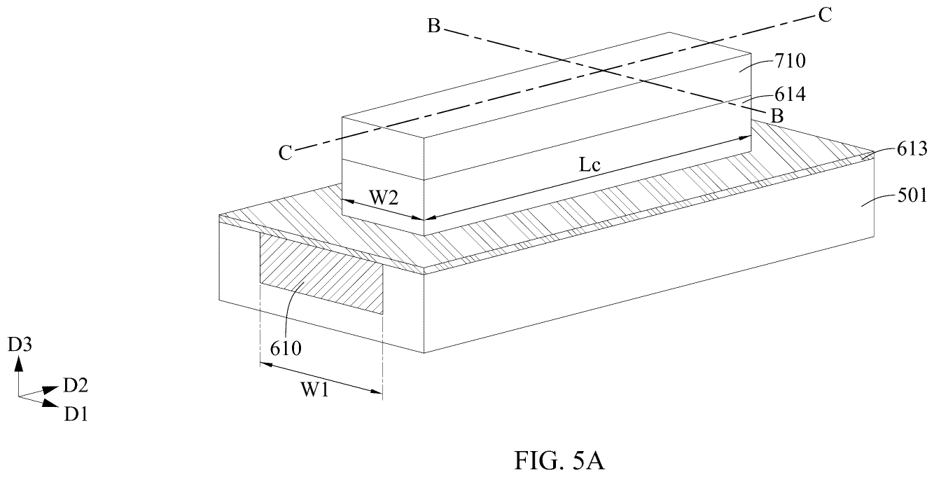

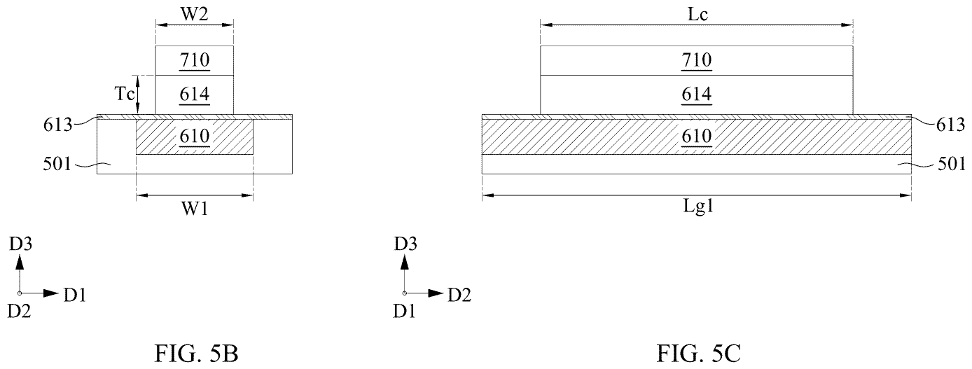

Referring to FIGS. 5A, 5B, 5C, and 16, method 1600 includes a block 1602 where a channel layer 614 is formed on the first gate dielectric layer 613.

In some embodiments, the mask layer 7100 is patterned such that it covers only a portion of the channel material layer 6140. The mask layer 7100 may include one or more hard mask (HM) layers and a photoresist layer on the one or more hard mask (HM) layers. In such embodiments, the photoresist layer is patterned by photolithography, and the pattern of the photoresist layer is then transferred to the one or more hard mask (HM) layers by an acceptable etching process, such as dry etching (e.g., RIE, NBE, or the like), wet etching, or a combination thereof. Thus, the mask layer 7100 is patterned to form a patterned mask 710.

Next, an etching process is performed using the patterned mask 710 as an etching mask to remove portions of the channel material layer 6140 uncovered by the patterned mask 710. Thus, the pattern of the patterned mask 710 is transferred into the channel material layer 6140 to form a channel layer 614. The etching process may include dry etching, wet etching, or a combination thereof. In some embodiments, the etching process is an anisotropic etching process.

In some embodiments, as illustrated in FIGS. 5A and 5B, the first gate electrode 610 has a width W1 in direction D1, and the channel layer 614 has a width W2 in direction D1. The width W1 of the first gate electrode 610 may be greater than or substantially equal to the width W2 of the channel layer 614. As illustrated in FIGS. 5A and 5C, the first gate electrode 610 has a length Lg1 in direction D2, and the channel layer 614 has a length Lc in direction D2. In some embodiments, the length Lg1 of the first gate electrode 610 is greater than the length Lc of the channel layer 614.

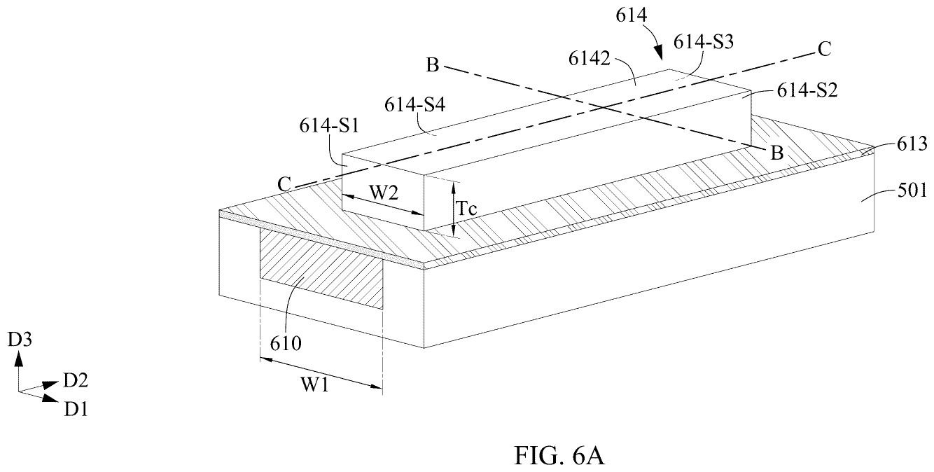

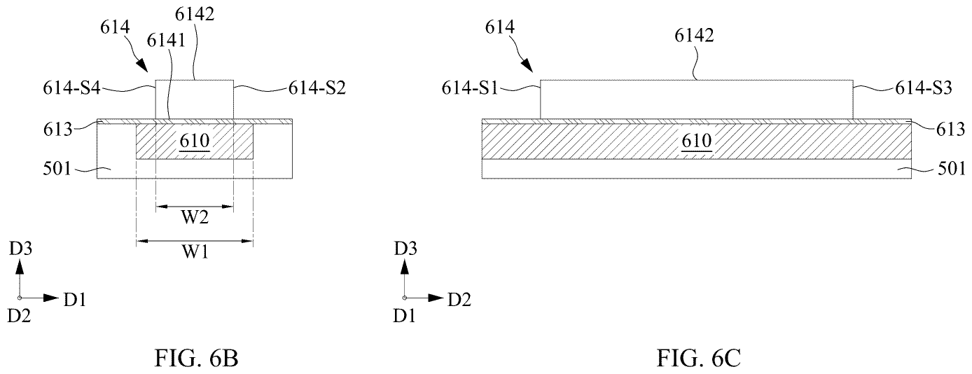

Referring to FIGS. 6A, 6B, and 6C, the patterned mask 710 is removed by an ashing process, a stripping process, or the like, or a combination thereof. In this exemplified embodiment, the channel layer 614 has a bottom surface 6141, a top surface 6142 opposite the bottom surface 6141, and four side surfaces. For example, the channel layer 614 has the first side surface 614-S1, the second side surface 614-S2, the third side surface 614-S3 opposite the first side surface 614-S1, and the fourth side surface 614-S4 opposite the second side surface 614-S2. The bottom surface 6141 of the channel layer 614 is in contact with the top surface 6132 of the first gate dielectric layer 613. In some embodiments, after the patterned mask 710 is removed, the top surface 6142 of the channel layer 614 provides a flat surface.

As illustrated in FIGS. 6A and 6C, in some embodiments, the channel layer 614 and the first gate electrode 610 extend in the same direction. That is, the channel layer 614 has a lengthwise direction (e.g., the direction D2) the same as a lengthwise direction of the first gate electrode 610. As illustrated in FIGS. 6A and 6B, in some embodiments, the channel layer 614 has a vertical projection on the first gate electrode 610, and the area of the vertical projection is located within the first gate electrode 610.

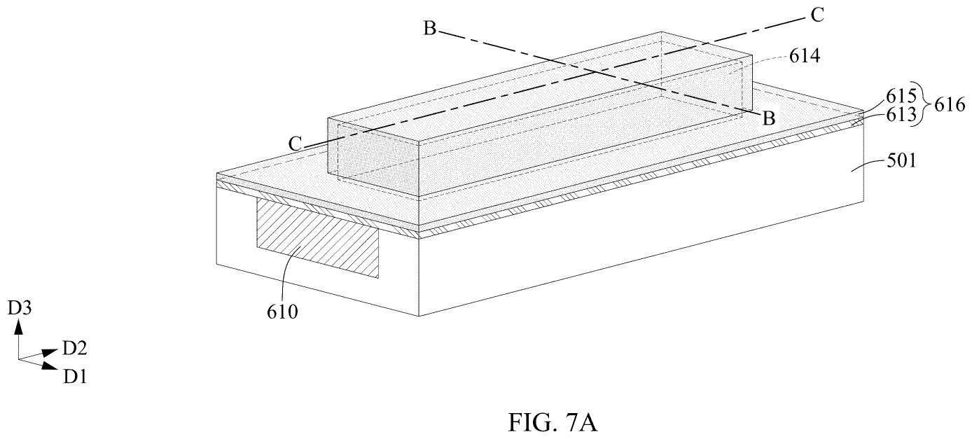

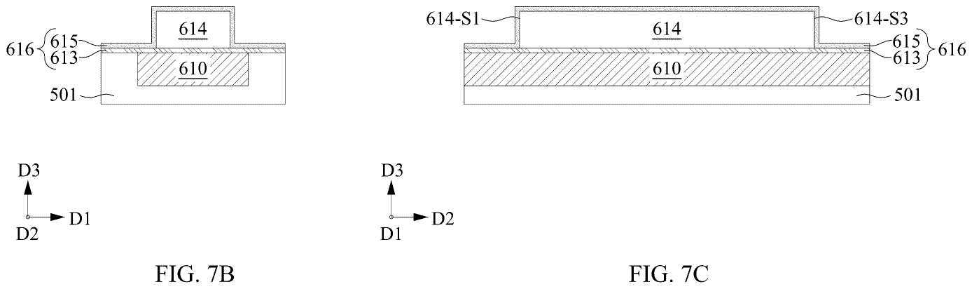

Referring to FIGS. 7A, 7B, 7C, and 16, method 1600 includes a block 1603 where a second gate dielectric layer 615 is formed on the first gate dielectric layer 613 and covers the channel layer 614.

In some embodiments, the second gate dielectric layer 615 is conformally deposited on the first gate dielectric layer 613 and covers exposed surfaces of the channel layer 614. For example, the second gate dielectric layer 615 covers the top surface 6142 and four side surfaces that include the first side surface 614-S1, the second side surface 614-S2, the third side surface 614-S3, and the fourth side surface 614-S4. The first gate dielectric layer 613 and the second gate dielectric layer 615 may be collectively referred to as a gate dielectric layer 616. Thus, after the second gate dielectric layer 615 is formed, the channel layer 614 is encapsulated by the gate dielectric layer 616.

The second gate dielectric layer 615 may include, but is not limited to, silicon nitride, hafnium oxide (HfO₂), hafnium silicon oxide (HfSiO), hafnium tantalum oxide (HfTaO), hafnium titanium oxide (HfTiO), hafnium zirconium oxide (Hf_{0.5}Zr_{0.5}O₂) (HZO), tantalum oxide (Ta₂O₅), aluminum oxide (Al₂O₃), hafnium dioxide-alumina (HfO₂—Al₂O₃), zirconium oxide (ZrO₂), titanium oxide (TiO₂), strontium titanium oxide (SrTiO₃), or another suitable high-k dielectric material. Other suitable dielectric materials are within the scope of the present disclosure. In some embodiments, the first gate dielectric layer 613 and the second gate dielectric layer 615 are formed of different gate dielectric materials. In some other embodiments, the first gate dielectric layer 613 and the second gate dielectric layer 615 are formed of the same gate dielectric material.

In some embodiments, the second gate dielectric layer 615 may have a thickness in the range of 0.5 nm to 5.0 nm, such as 1 nm to 4 nm, although greater or lesser thicknesses may also be used. The second gate dielectric layer 615 may be formed by ALD, and has a thickness measured in direction D3, ranging between 1 nm and 3 nm. These numerical values are provided for exemplification purposes only and are not intended to be limiting. In addition, the first gate dielectric layer 613 and the second gate dielectric layer 615 may have different thicknesses or the same thickness.

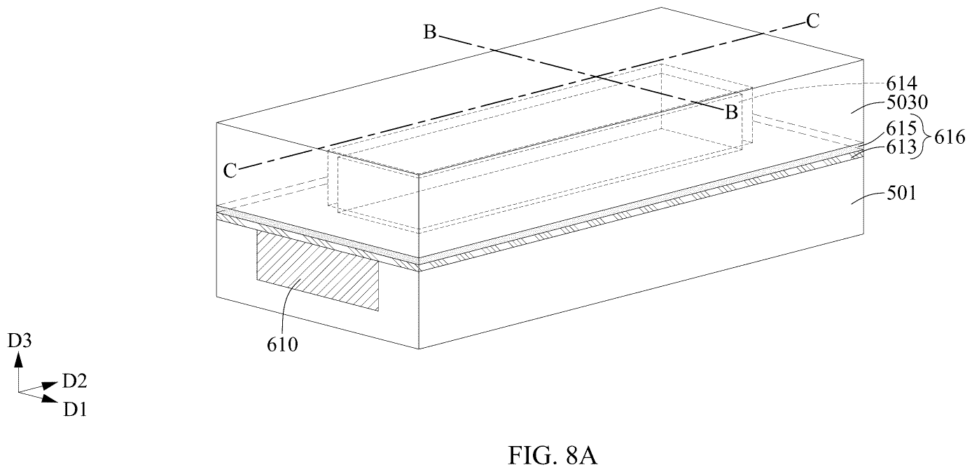

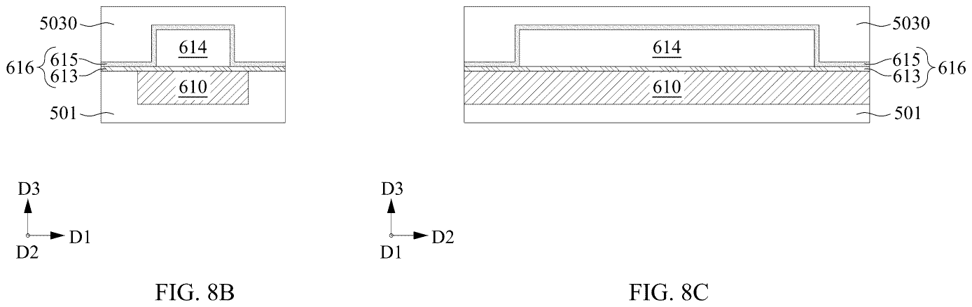

Referring to FIGS. 8A, 8B, and 8C, an insulating material 5030 is formed on the second gate dielectric layer 615. In some embodiments, the insulating material 5030 includes silicon oxide, silicon nitride, silicon oxynitride, another suitable insulating material, or a combination thereof. The insulating material 5030 may be formed using, for example, chemical vapor deposition (CVD), atomic layer deposition (ALD), physical vapor deposition (PVD), plasma-enhanced CVD (PECVD), or the like.

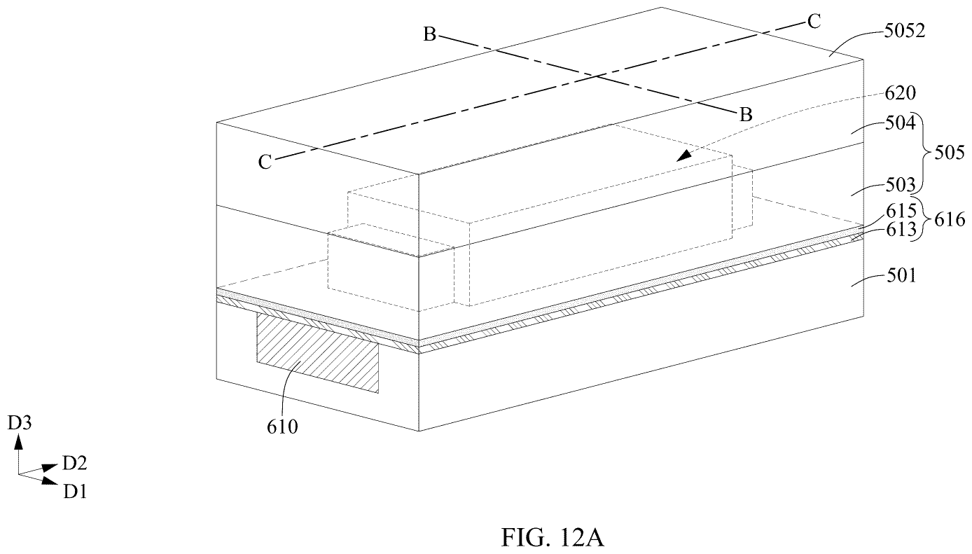

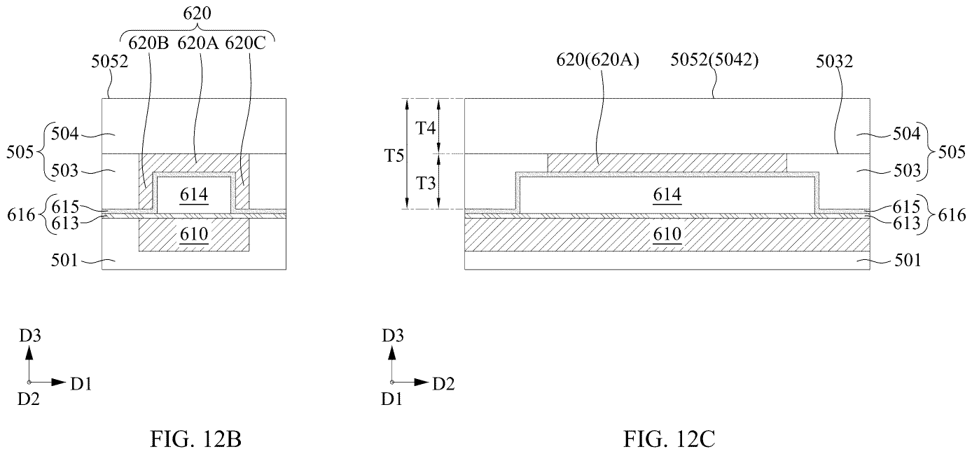

Specifically, in some embodiments, the channel layer 614 and portions of the second gate dielectric layer 615 that are conformally on the channel layer 614 collectively form a fin-like protrusion on the first gate dielectric layer 613. The insulating material 5030 may be deposited on the second gate dielectric layer 615 to cover the fin-like protrusion excessively. The thickness of the excess amount of the insulating material 5030, measured from the uppermost surface of the second gate dielectric layer 615 to the top surface of the insulating material 5030 in the direction of D3, may be determined by the thickness of a top portion 620A of the second gate electrode 620 (FIG. 12B) subsequently formed on the second gate dielectric layer 615.

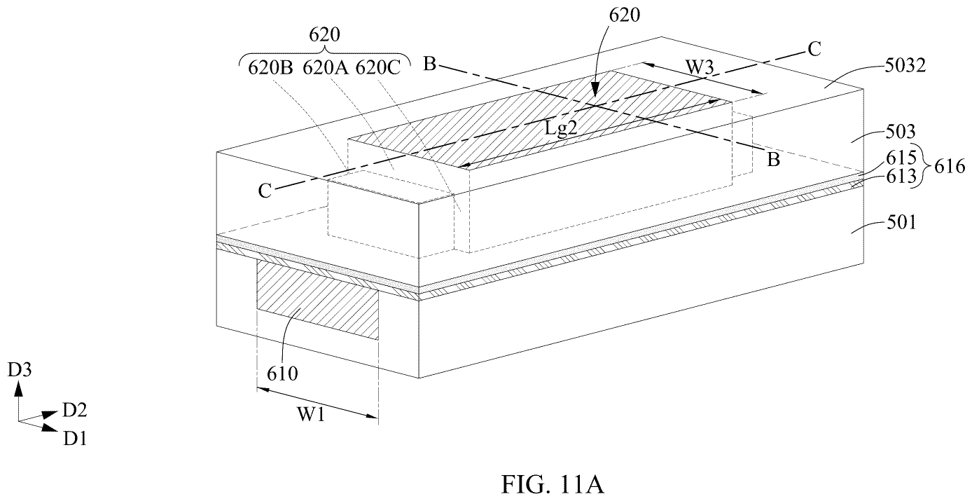

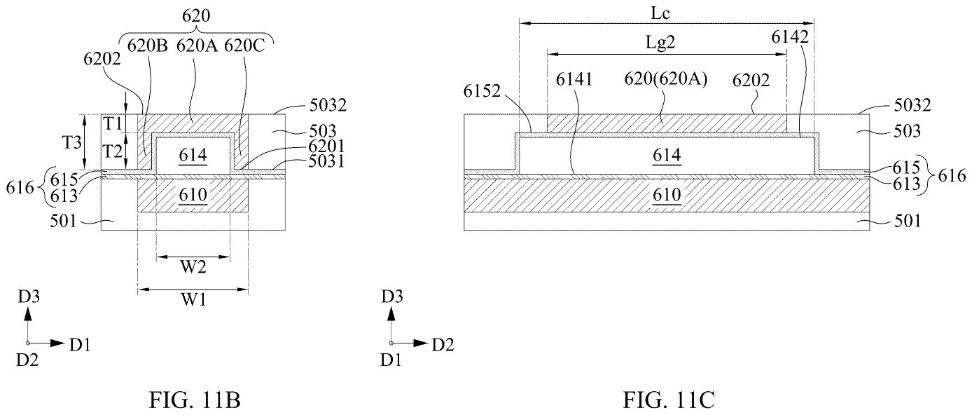

Next, referring to FIG. 16, method 1600 includes a block 1604, where a second gate electrode 620 (e.g., shown in FIG. 11B) is formed on the second gate dielectric layer 615 and extends over three sides of the channel layer 614.

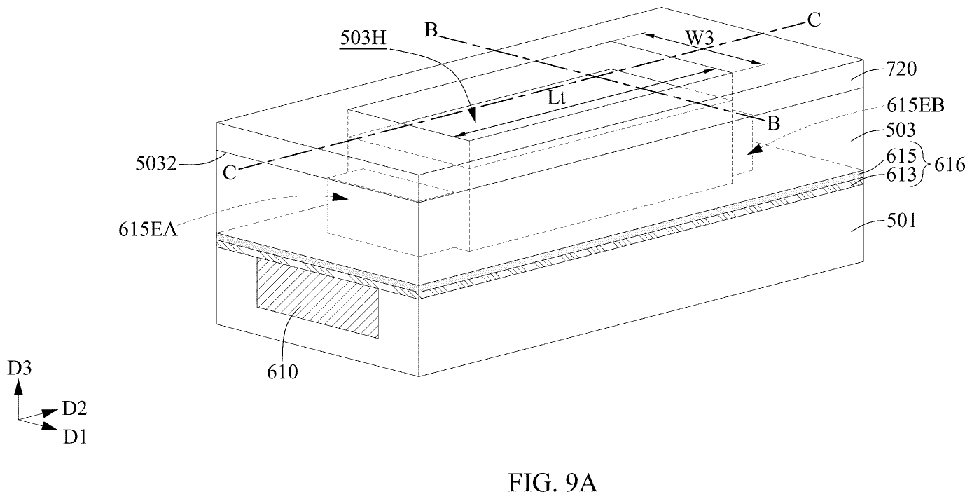

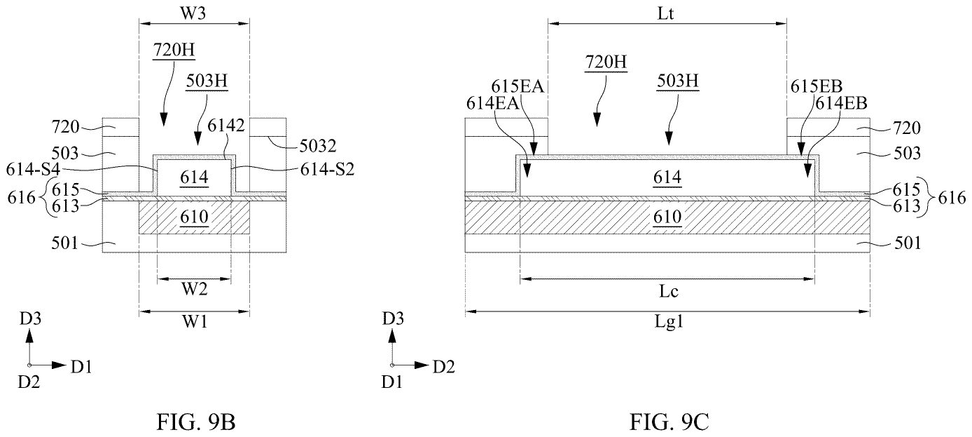

Referring to FIGS. 9A, 9B, and 9C, a patterned photoresist layer 720 is formed on the insulating material 5030 (FIGS. 8A, 8B, and 8C), and its pattern is transferred to the insulating material 5030.

In some embodiments, the patterned photoresist layer 720 may be formed by applying a photoresist layer (not shown) over the top surface 5032 of the insulating material 5030, and may be lithographically patterned to form an opening 720H within the illustrated area. The opening 720H may be a rectangular opening having a pair of widthwise sidewalls along the direction D1 and having a pair of lengthwise sidewalls along the direction D2. The opening 720H may have any suitable shape when viewed from the top. An anisotropic etch process may be performed to transfer the pattern of the opening 720H in the photoresist layer to a portion of the insulating material 5030, so as to form an insulating layer 503 having a trench 503H. The trench 503H and the opening 720H have substantially the same dimension.

In some embodiments, the trench 503H of the insulating layer 503 exposes portions of the second gate dielectric layer 615 and extends across three sides of the channel layer 614. The depth of the trench 503H may be equal to the thickness of the insulating layer 503. It is noted that parts 615EA and 615EB of the second gate dielectric layer 615, which cover two opposite end portions 614EA and 614EB of the channel layer 614, remained covered by the insulating layer 503 and are not exposed in the trench 503H. In some embodiments, the trench 503H has a length Lt in direction D2. In some embodiments, the length Lt of the trench 503H is less than the length Lc of the channel layer 614. The trench 503H of the insulating layer 503 is also referred to as a top gate trench. The patterned photoresist layer 720 may be subsequently removed, for example, by ashing.

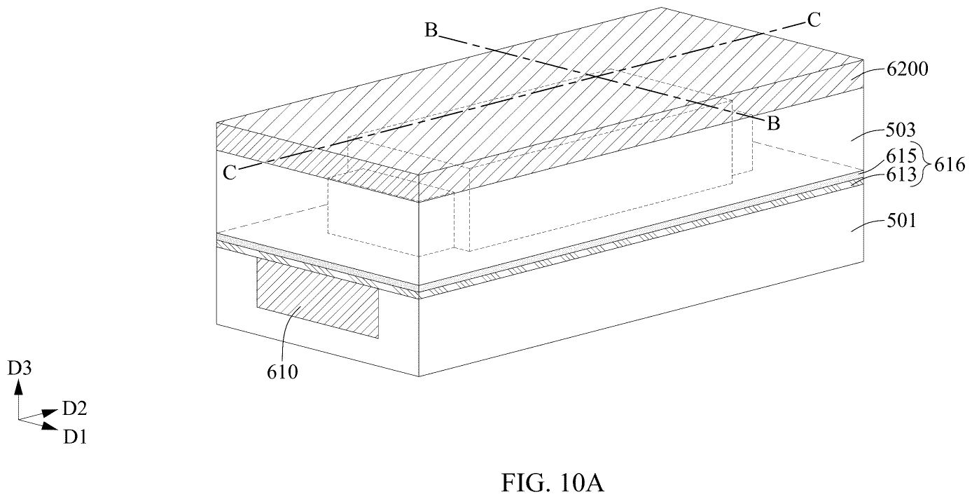

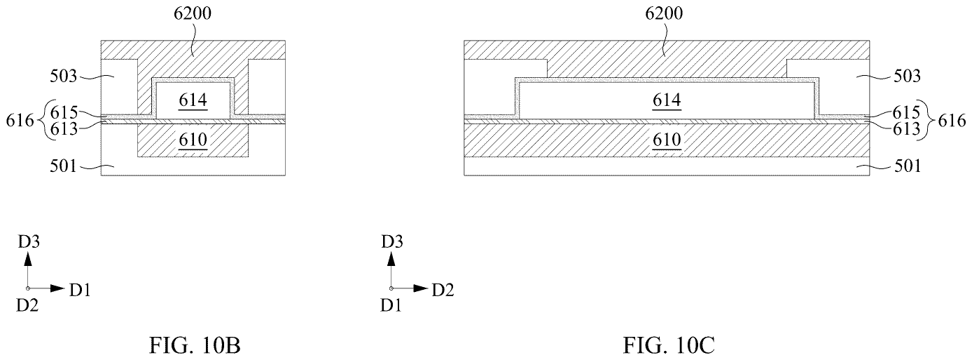

Next, referring to FIGS. 10A, 10B and 10C, at least one conductive material 6200 may be excessively formed on the insulating layer 503 and fill up the trench 503H of the insulating layer 503. The at least one conductive material 6200 may have a single-layered structure or a multi-layered structure, including two or more conductive material layers. The at least one conductive material 6200 may include, for example, a metallic barrier liner material (not shown) (such as TiN, TaN, WN, or any suitable barrier material) and a metallic fill material. In some embodiments, the metallic fill material of the conductive material 6200 includes copper, aluminum, zirconium, titanium, tungsten, tantalum, tantalum nitride, ruthenium, palladium, platinum, cobalt, nickel, iridium, alloys thereof, another suitable metallic fill material, or a combination thereof. Other suitable metallic liner and metallic fill materials within the contemplated scope of disclosure may also be used. For the sake of simplicity and clarity, the conductive material 6200 with a single-layered structure is depicted in the drawings.

The at least one conductive material 6200 may be deposited by a chemical vapor deposition (CVD) process, a physical vapor deposition (PVD) process, an atomic layer deposition (ALD) process, a sputtering process, laser ablation, or any suitable process. The CVD process may include a high density plasma CVD (HDPCVD) process, a metal organic CVD (MOCVD) process, a plasma enhanced CVD (PECVD) process, or any suitable method.

Next, referring to FIGS. 11A, 11B, and 11C, a planarization process, such as a chemical mechanical polishing (CMP) process or the like, may then be performed to remove excess portions of the at least one conductive material 6200 above the top surface 5032 of the insulating layer 503. The remaining portion of the at least one conductive material 6200 in the trench 503H is referred to as a second gate electrode 620. After planarization, the top surface 5032 of the insulating layer 503 is exposed and coplanar with the top surface 6202 of the second gate electrode 620.

In some embodiments, the second gate electrode 620 extends across three sides of the channel layer 614 (e.g., along the direction D1). The second gate electrode 620 may include a top portion 620A and two side portions 620B and 620C. In some embodiments, the second gate electrode 620 has an inverted U-shaped cross-section (FIGS. 11A and 11B). The top portion 620A has a thickness T1 measured from the uppermost surface 6152 of the second gate dielectric layer 615 to the top surface of the second gate electrode 620 in direction D3. The side portions 620B and 620C each have a thickness T2, measured from the top surface of the portion of the second gate dielectric layer 615 on the first gate dielectric layer 613 to the uppermost surface 6152 of the second gate dielectric layer 615 in direction D3. The thickness T3 of the second gate electrode 620 may be the sum of the thickness T1 of the top portion 620A and the thickness T2 of each side portion 620B and 620C.

As illustrated in FIGS. 11A and 11C, the second gate electrode 620 has a length Lg2 in direction D2. In some embodiments, the length Lc of the channel layer 614 is greater than the length Lg2 of the second gate electrode 620. As illustrated in FIG. 11B, the second gate electrode 620 has a width W3 in direction D1. Although the second gate electrode 620 and the first gate electrode 610, which have substantially the same width, are exemplified in this embodiment, the present disclosure is not limited thereto. The width W3 of the second gate electrode 620 may be less than, greater than, or substantially equal to the width W1 of the first gate electrode 610.

In some embodiments, the first gate electrode 610 and the second gate electrode 620 are two gate electrodes of a transistor to be subsequently formed. The first gate electrode 610 and the second gate electrode 620 are positioned adjacent to opposite sides (e.g., the bottom side and the top side) of the channel layer 614. For example, the first gate electrode 610 is located adjacent to the bottom surface 6141 of the channel layer 614. The first gate electrode 610 is separated from the channel layer 614 by the first gate dielectric layer 613. The second gate electrode 620 is located adjacent to the top surface 6142 of the channel layer 614. The second gate electrode 620 is separated from the channel layer 614 by the second gate dielectric layer 615. The first gate electrode 610 and the second gate electrode 620 may be referred to as a bottom gate electrode and a top gate electrode, respectively.

Next, referring to FIGS. 12A-12C, 13A-13C, 14A-14C, and 16, method 1400 includes a block 1605, where source/drain features 623 are formed on the second gate dielectric layer 615 and connected to opposite ends of the channel layer 614. A source/drain feature 623 may refer to a source or a drain, individually or collectively, depending upon the context.

Referring to FIGS. 12A, 12B, and 12C, in some embodiments, another insulating layer 504 is formed on the insulating layer 503 after the second gate electrode 620 is formed and leveled to the insulating layer 503. The insulating layer 504 may be formed by depositing an insulating material on the insulating layer 503. The insulating layer 504 extends continuously with a substantially uniform thickness (e.g., T4) and provides a flat top surface 5042. The insulating layer 503 may be referred to as a first insulating layer, and the insulating layer 504 may be referred to as a second insulating layer. In these exemplified embodiments, the insulating layers 503 and 504 are collectively referred to as an insulation 505.

In some embodiments, the thickness T4 of the insulating layer 504 is measured from the top surface 5032 of the insulating layer 503 to the top surface 5042 of the insulating layer 504 in direction D3. The thickness T5 of the insulation 505 may be the sum of the thickness of the insulating layer 503 (i.e., the thickness T3 of the second gate electrode 620) and the thickness T4 of the insulating layer 504. The thickness T5 varies with the depth of the source/drain features to be subsequently formed. Thus, the thickness T4 of the insulating layer 504 can be adjusted to produce an insulation 505 with sufficient thickness T5, allowing for the subsequent formation of the source/drain features with a predetermined height within the insulation 505 later on. Thus, the method of the embodiments also provides a simple way to adjust the height of the source/drain features formed subsequently.

In some embodiments, the insulating layer 504 includes silicon oxide, silicon nitride, silicon oxynitride, another suitable insulating material, or a combination thereof. The insulating layer 504 may be formed using, for example, chemical vapor deposition (CVD), atomic layer deposition (ALD), physical vapor deposition (PVD), plasma-enhanced CVD (PECVD), or the like. The insulating layers 504 and 503 may include the same material or different materials. In some embodiments, the insulating layers 504 and 503 are formed of the same insulating material.

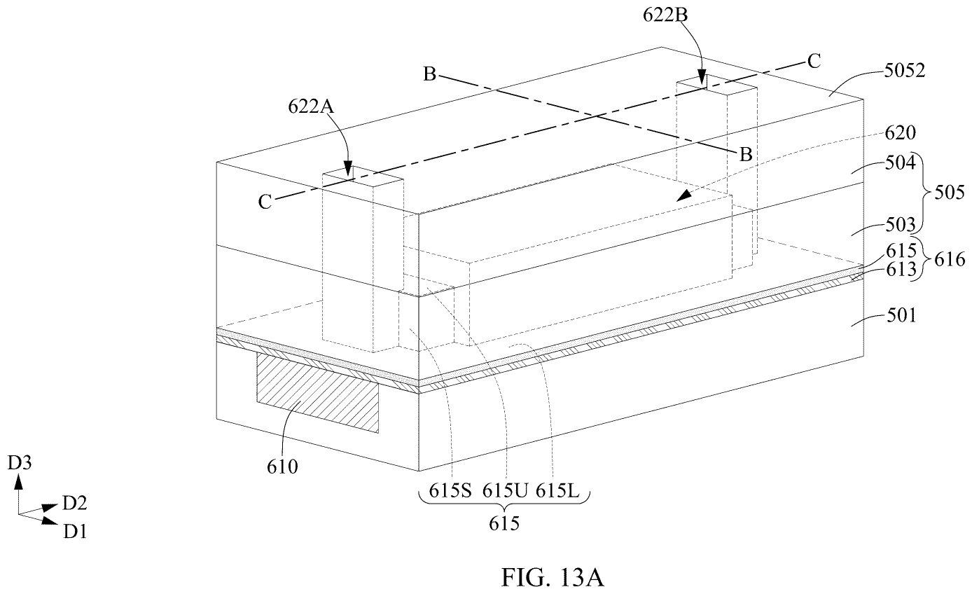

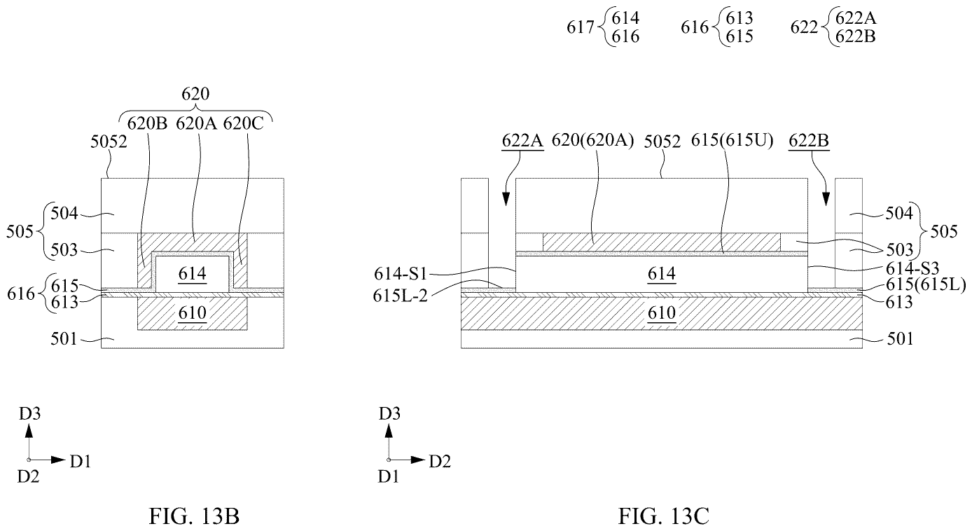

Referring to FIGS. 13A, 13B, and 13C, in some embodiments, the trenches 622 (including the trenches 622A and 622B) are formed in the insulation 505 and located adjacent to opposite ends of the channel layer 614. In some embodiments, portions of the insulation 505 and at least portions of the second gate dielectric layer 615 on opposite ends of the channel layer 614 are removed to form the trenches 622A and 622B. In some embodiments, the remaining portion of the second gate dielectric layer 615 that is on the three sides of the channel layer 614 has an inverted U-shaped cross-section.

Specifically, the trenches 622A and 622B each penetrate the insulating layers 504 and 503. After the trenches 622A and 622B are formed in the insulation 502, the second gate dielectric layer 615 includes an upper part 615U, remaining sidewall parts 615S (e.g., on the side surfaces 614-S1 and 614-S3 of the channel layer 614), and a lower part 615L on the first gate dielectric layer 613. In some embodiments, as shown in FIGS. 13A and 13C, the trenches 622A and 622B are vertically (e.g., along the direction D3) extended to expose the top surface 615L-2 of the lower part 615L of the second gate dielectric layer 615.

The formation of the trenches 622A and 622B may include applying a photoresist layer (not shown) over the top surface 5052 of the insulation 505, and may be lithographically patterned to form openings (not shown) within the illustrated area. An anisotropic etch process may be performed to transfer the pattern of the openings in the photoresist layer to the insulation 505, so as to form the trenches 622A and 622B in the insulation 505. Subsequently, the photoresist layer is subsequently removed, for example, by ashing.

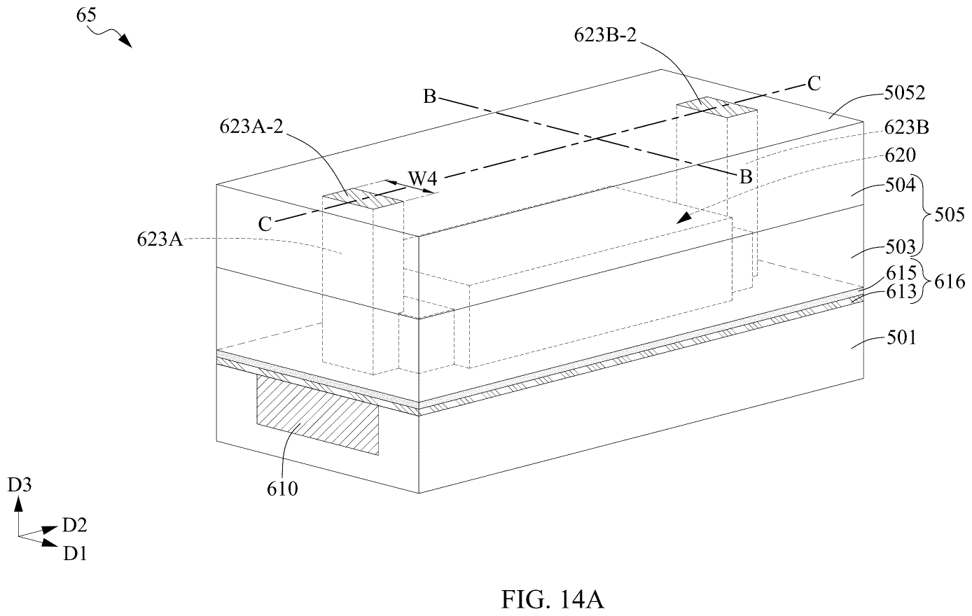

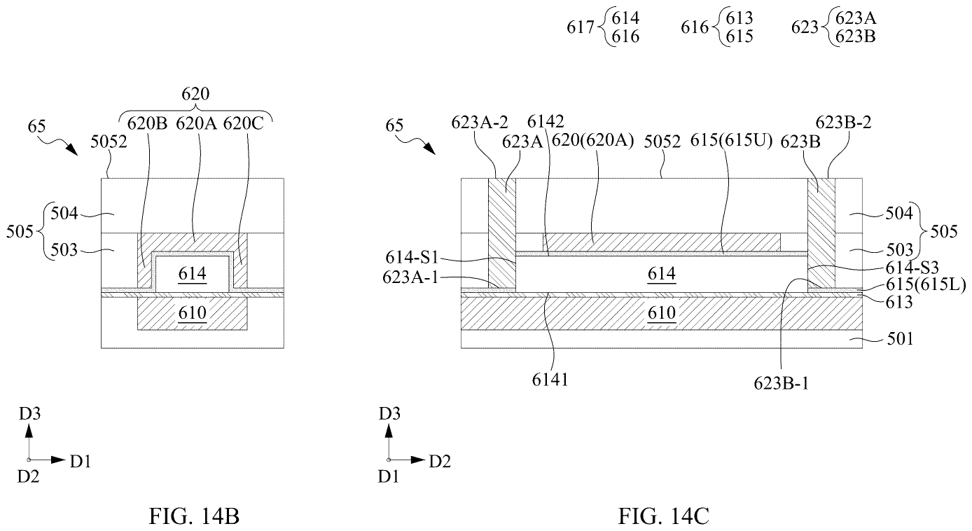

Next, referring to FIGS. 14A, 14B and 14C, in some embodiments, source/drain features 623A and 623B are formed in the trenches 622A and 622B, respectively. The source/drain features 623A and 623B are vertically extended into the insulation 502 and formed on the second gate dielectric layer 615. The source/drain features 623A and 623B are laterally separated from each other (e.g., in direction D2) at opposite ends of the channel layer 614. In some embodiments, the bottom surface 6141 of channel layer 614 is lower than the bottom surfaces 623A-1 and 623B-1 of the source/drain features 623A and 623B. In some embodiments, the source/drain contacts are separated from each other along the lengthwise direction (e.g., the direction D2) of channel layer 614. The source/drain features 623A and 623B may be collectively referred to as source/drain features 623 hereinafter.

In some embodiments, the source/drain features 623A and 623B are in lateral contact with opposite ends of the channel layer 614. For example, the source/drain feature 623A is in lateral contact with the side surface 614-S1 of the channel layer 614, and the source/drain feature 623B is in lateral contact with the side surface 614-S3 of the channel layer 614.

In some embodiments, as shown in FIGS. 14A and 14C, the source/drain features 623A and 623B are laterally (e.g., along the direction D2) separated from the second gate electrode 620 by the insulating layer 503. In some embodiments, the source/drain features 623A and 623B are vertically (e.g., along the direction D3) separated from the first gate electrode 610 by the first gate dielectric layer 613 and the lower part 615L of the second gate dielectric layer 615. Since the lower part 615L of the second gate dielectric layer 615 is positioned between the first gate dielectric layer 613 and the source/drain features 623A/623B, the bottom surface 623A-1 of the source/drain feature 623A and the bottom surface 623B-1 of the source/drain feature 623B are located above the level of the top surface 6132 of the first gate dielectric layer 613.

In addition, the source/drain features 623 have the width W4 in direction D1. Although the width W4 of the source/drain features 623, as shown in FIG. 14A, is less than the width W2 of the channel layer 614, the present disclosure is not limited to this configuration. The width W4 of the source/drain features 623 may be less than, greater than, or substantially equal to the width W2 of the channel layer 614.

The source/drain features 623A and 623B may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. Other suitable metallic liner and metallic fill materials within the contemplated scope of disclosure may also be used.

The formation of the source/drain features 623A and 623B may include excessively deposited an electrically conductive material on the insulation 505, fully filling the trenches 622A and 622B. Then, a planarization process, such as a chemical mechanical polishing (CMP) process or the like, may then be performed to remove excess amounts of the electrically conductive material from the top surface 5052 of the insulation 505, thereby forming the source/drain feature 623A in the trenches 622A and the source/drain feature 623B in the second trench 622B. After planarization, the top surface 623A-2 of the source/drain feature 623A and the top surface 623B-2 of the source/drain feature 623B are coplanar with the top surface 5052 of the insulation 505.

According to the above description, in some embodiments, a TFT 65 may include a first gate electrode 610 over a substrate, a multilayered structure 617, a second gate electrode 620, and two source/drain features 623. The multilayered structure 617 may include a first gate dielectric layer 613 on the first gate electrode 610, a channel layer 614, and a second gate dielectric layer 615 on the first gate dielectric layer 613. The channel layer 614 is covered by the first gate dielectric layer 613 and the second gate dielectric layer 615. The second gate electrode 620 is formed on the second gate dielectric layer 615 and across three sides of the channel layer 614. The source/drain features 623 (or may be referred to as source/drain contacts) are formed on the second gate dielectric layer 615 and in contact with opposite side surfaces (e.g., the first side surface 614-S1 and the third side surface 614-S3) of the channel layer 614. The multilayered structure 617 may be referred to as a selector layer of the TFT 65. The TFT is configured to selectively supply power to a memory cell subsequently formed on one of the source/drain features 623 (e.g., formed on a drain contact). In some embodiments, suitable voltages can be applied to the first gate electrode 610 and the second gate electrode 620 during operation of the TFT 65.

In some embodiments, the first gate electrode 610 is positioned at the bottom side of the channel layer 614, and the second gate electrode 620 extends across three sides of the channel layer 614 (e.g., can be collectively regarded as a GAA-like electrode structure), thereby improving the electrical performances of the transistor, especially for transistors that include semiconducting oxide materials (such as IGZO or other suitable materials). For example, short-channel effects (SCEs) can be reduced when the gate length of the transistor shrinks, and leakage current can be reduced when the channel length of the transistor is scaled down. In addition, the forming methods of some embodiments provide a simple way to form a GAA-like electrode structure without the need for performing complex GAA-like processes.

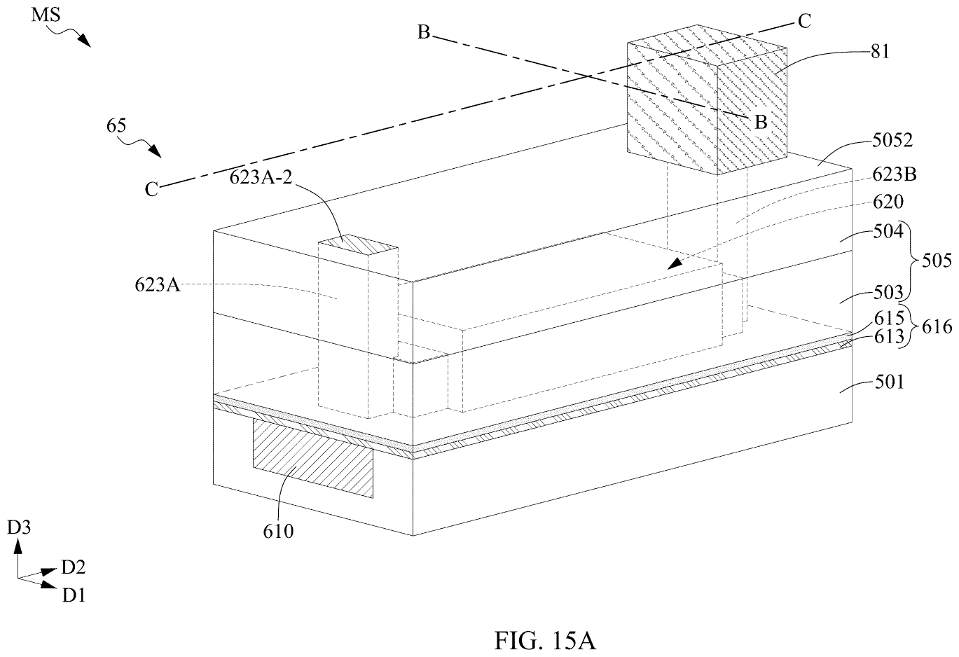

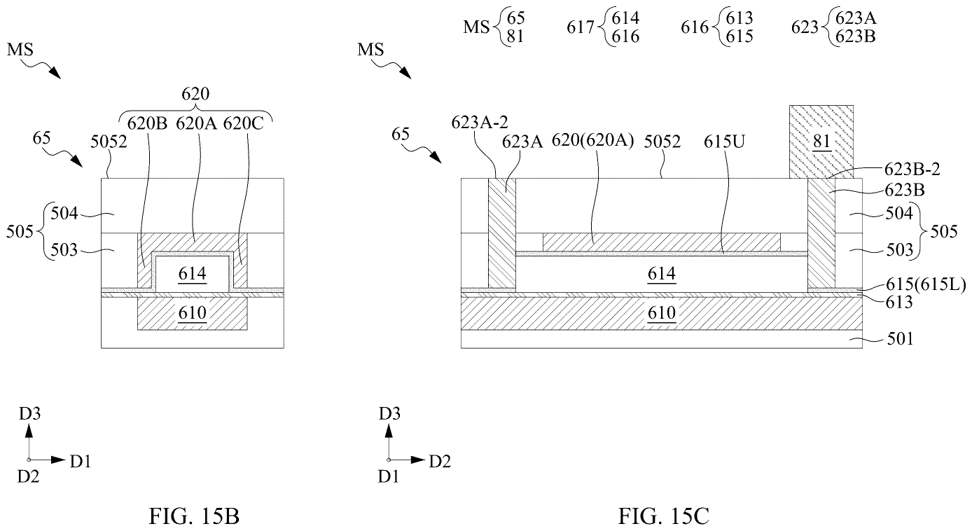

Referring to FIGS. 15A, 15B and 15C, in some embodiments, method 1600 includes a block 1606 where a memory cell 81 is formed on one of the source/drain features 623A and 623B of a memory structure. The memory cell 81 may be a volatile memory cell or a nonvolatile (NV) memory cell as desired.

As described above, in some embodiments, an array 50 of memory structures is formed in the memory array region A1 and over the second interconnect-level structure L2 (FIG. 2). In some embodiments, each of the memory structures may include a transistor (such as a TFT 65 as described above), and a memory cell (such as a memory cell 81 as described above) on the transistor and coupled to the transistor. The transistor may act as a selector for the memory cell formed thereon.

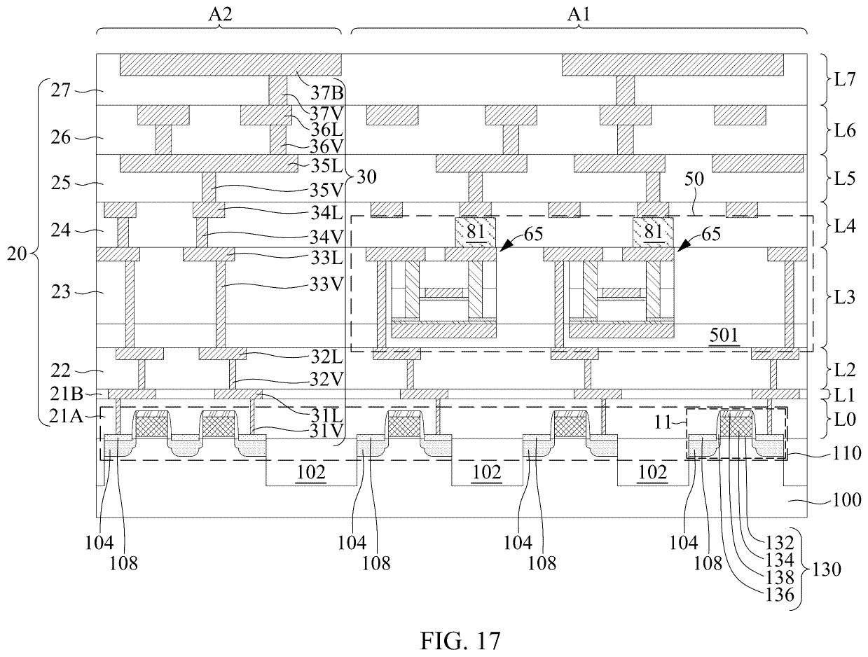

FIG. 17 is a cross-sectional view of an exemplary semiconductor structure with upper-level metal interconnect structures, including an array 50 of memory structures, in accordance with some embodiments of the present disclosure. The memory structures MS, as shown in FIGS. 15A, 15B and 15C, are formed within the semiconductor structure. In some embodiments, the transistors of the memory structures, such as the TFTs 65 of the memory structures MS, are formed at the third level of the semiconductor structure and are parts of the third interconnect-level structure L3. The memory cells on the TFTs, such as the memory cells 81, may be formed at the fourth level and may be parts of a fourth interconnect-level structure L4. As shown in FIG. 17, the memory cells 81 are formed within the dielectric layer 24 of the fourth interconnect-level structure L4. Applicable memory cells of an array 50 of memory structures may include volatile memory cells or nonvolatile (NV) memory cells. Emerging nonvolatile memory technologies include resistive random-access memory (RRAM or ReRAM), magnetic/magneto-resistive random-access memory (MRAM), ferroelectric random-access memory (FeRAM), and phase-change memory (PCM), for example.

In some embodiments, the CMOS circuitry 110 includes several field-effect transistors (FETs) 11. After forming a FEOL structure, such as structures (e.g., FETs) on the substrate 100 and the lower interconnect-level structures (L0, L1, L2), the third level of the semiconductor structure, which includes the TFTs 65, is formed on the FEOL structure. The TFTs 65 are coupled to the FETs 11.

Specifically, in some embodiments, one of the source/drain features 623 of a TFT 65 is coupled to the FET 11 by the third interconnect-level metal interconnect structures (33V, 33L), the second interconnect-level metal interconnect structures (32V, 32L), the first metal lines 31L, and the contact via structure 31V, as shown in FIG. 17. The FETs 11 may supply power to the TFTs 65. Similarly, one of the source/drain features 623 of each TFT 65 is coupled to the FET 11 through the third interconnect-level metal interconnect structures (33V, 33L), the second interconnect-level metal interconnect structures (32V, 32L), the first metal lines 31L, and the contact via structure 31V.

In some embodiments, the TFTs 65 of the memory structures MS are electrically independent from each other. The TFTs 65 can be controlled independently by the FETs 11. In some embodiments, some of the second gate electrodes 620 (e.g., top gate electrodes 620) of the TFTs 65 can be electrically connected, and simultaneously controlled by applying a suitable voltage.

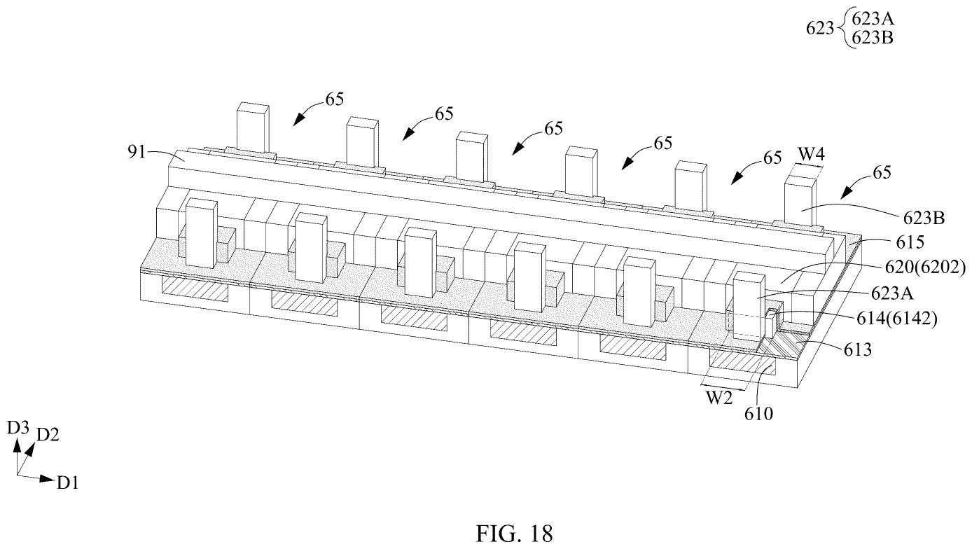

FIG. 18 illustrates a portion of an array of memory structures, in accordance with some embodiments of the present disclosure. As shown in FIG. 18, the width W4 of the source/drain features 623 may be less than the width W2 of the channel layer 614. The source/drain features 623 may be in contact with the outermost sidewalls (e.g., the side surfaces 614-S1 and 614-S3) of the channel layer 614.

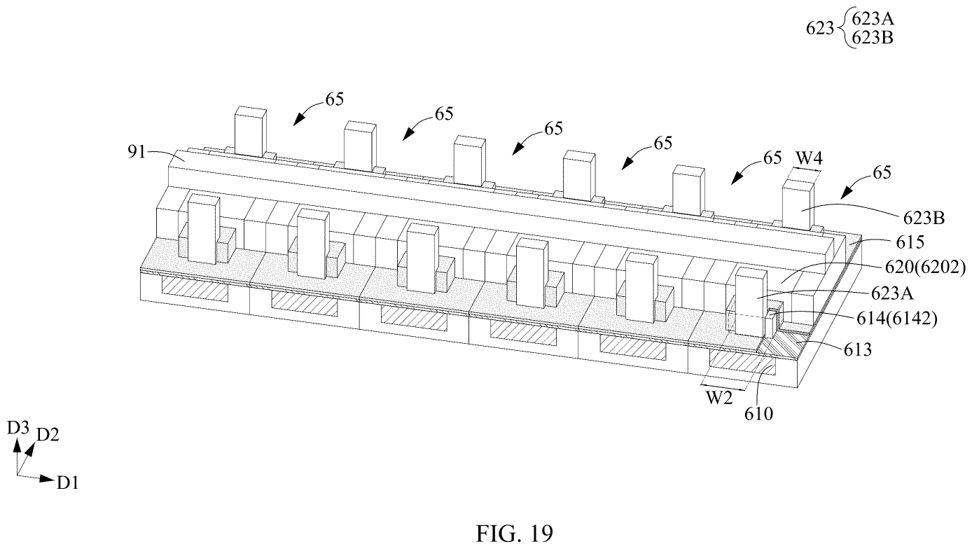

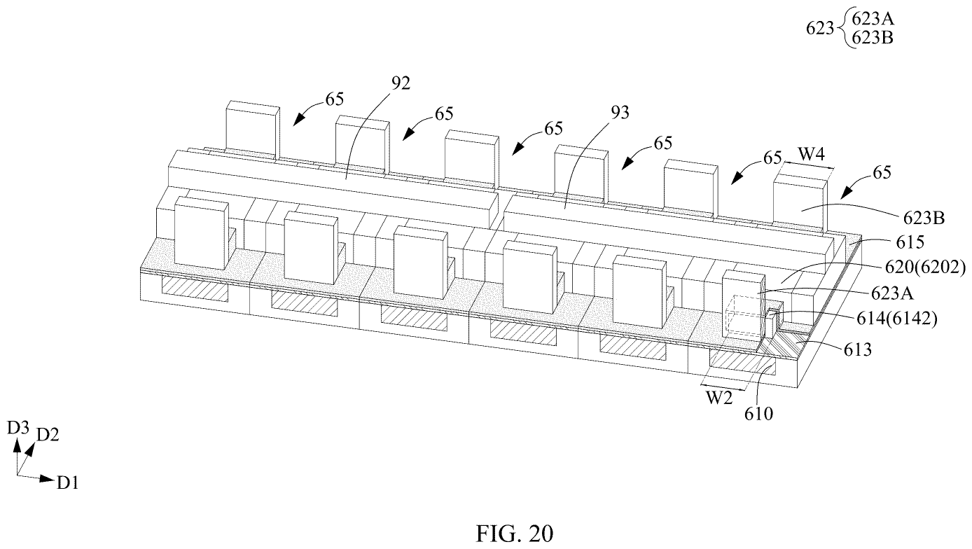

The features/components in FIG. 18 that are similar or identical to the features/components in FIGS. 15A-15C are designated with similar or the same reference numbers, and the details of those similar or the identical features/components are not repeated herein. In addition, for the sake of simplicity and clarity, parts of the insulation 505 and the memory cells (such as the memory cells 81 in FIG. 17) of the memory structures are omitted in FIG. 18 (as well as FIGS. 19-20).

In some embodiments, the second gate electrodes 620 of the TFTs 65 of several memory structures are electrically connected to each other and can be referred to as a common top gate electrode. For example, a common conductive line 91 may be formed on the top surfaces 6202 of the second gate electrodes 620 of the TFTs 65. Thus, the second gate electrodes 620 may be easily controlled by applying a suitable voltage to the common conductive line 91, in accordance with some embodiments of the present disclosure.

The common conductive line 91 may be a metal line, and may include copper, aluminum, zirconium, titanium, tungsten, tantalum, tantalum nitride, ruthenium, palladium, platinum, cobalt, nickel, iridium, another conductive material, or a combination thereof. Other suitable conductive materials within the contemplated scope of disclosure may also be used. The common conductive line 91 and the second gate electrodes 620 may include the same or different conductive materials. The conductivity of the common conductive line 91 can be, but is not limited to, greater than the conductivity of the second gate electrode 620.

FIG. 19 illustrates a portion of an array of memory structures, in accordance with some embodiments of the present disclosure. The major difference between the structures of FIG. 19 and FIG. 18 is that the source/drain features 623 in FIG. 19 are located closer to the second gate electrode 620. That is, a greater area of the lateral surfaces of each of the source/drain features 623 in FIG. 19 is covered by the channel layer 614.

In FIG. 19, a common conductive line 91 is formed on the top surfaces 6202 of the second gate electrodes 620 of the TFTs 65. Thus, the second gate electrodes 620 can be controlled simultaneously by applying a suitable voltage to the common conductive line 91.

FIG. 20 illustrates a portion of an array of memory structures, in accordance with some embodiments of the present disclosure. As shown in FIG. 20, the width W4 of the source/drain features 623 may be substantially equal to the width W2 of the channel layer 614. The source/drain features 623 may be in contact with the outermost sidewalls (e.g., the side surfaces 614-S1 and 614-S3) of the channel layer 614.

In some embodiments, the second gate electrodes of the TFTs 65 are electrically controlled in sections. For example, the second gate electrodes 620 of some TFTs 65 are electrically connected by a common conductive line 92, while the second gate electrodes 620 of other TFTs 65 are electrically connected by another common conductive line 93. The common conductive line 92 is electrically isolated from the common conductive line 93. The implementation can be selected and varied depending on the actual needs.

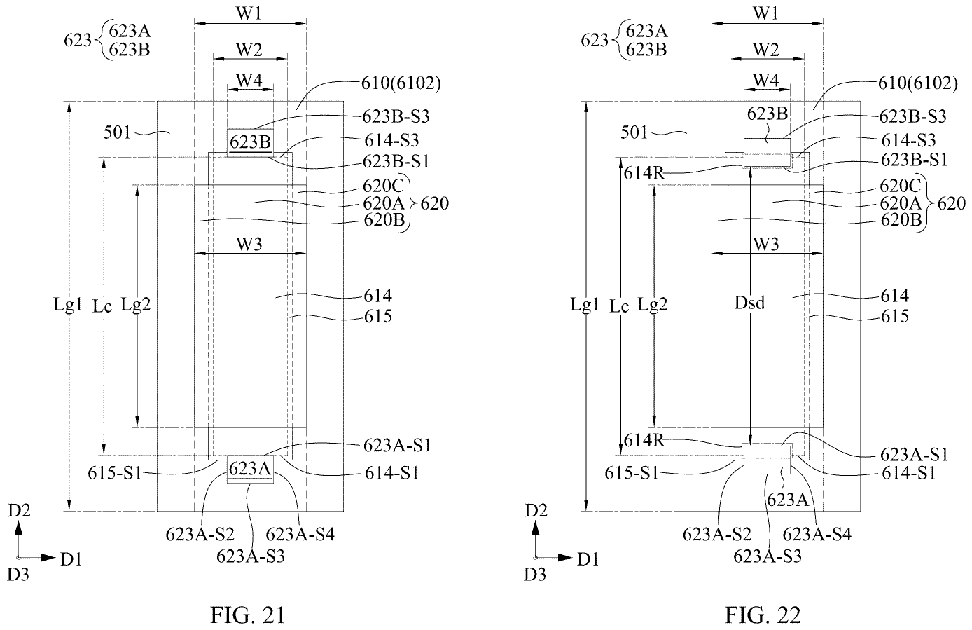

FIGS. 21-24 are top views each depicting a transistor of a memory structure, in accordance with some embodiments of the present disclosure. The features/components in FIGS. 21-24 that are similar or identical to the features/components in FIGS. 15A-15C are designated with similar or the same reference numbers, and the details of those similar or the identical features/components are not repeated herein.

In addition, it should be noted that the configurations (such as positions and dimensions) of the related components of the transistors in those top views are provided only for exemplification, not for limitation. For example, the source/drain features 623 may have square, rectangular, round, or any other suitable shape when viewed from the top. The related positions between the source/drain features 623, the channel layer 614, and the second gate electrode 620 can be altered without performing complex processes. The present disclosure is not limited to the exemplary patterns of the related components of the transistors.

In some embodiments, as illustrated in FIGS. 21-24, the channel layer 614 having a vertical projection (e.g., having the width W2) on the first gate electrode 610 (e.g., having the width W1). The area of the vertical projection of the channel layer 614 on the first gate electrode 610 is positioned within the top surface 6102 of the first gate electrode 610.

In some embodiments, as illustrated in FIG. 21, the width W4 of the source/drain features 623 is less than the width W2 of the channel layer 614. The source/drain features 623 are in contact with the outermost sidewalls (e.g., the side surfaces 614-S1 and 614-S3) of the channel layer 614.

In some embodiments, as illustrated in FIG. 22, the width W4 of the source/drain features 623 is less than the width W2 of the channel layer 614. The source/drain features 623 are in contact with opposite ends of the channel layer 614. The related positions between t he source/drain features 623, the channel layer 614, and the second gate electrode 620 can be modified to meet application requirements, such as adhering scaling-down constraints or enhancing electrical performance. In this example, the opposite ends of the channel layer 614 have recessed regions 614R for receiving a portion of each source/drain features 623 when viewed from the top.

As illustrated in FIG. 22, in some embodiments, the lateral surface 623A-S1 of the source/drain feature 623A is closer to the second gate electrodes 620 than the first side surface 614-S1 of the channel layer 614. Similarly, the lateral surface 623B-S1 of the source/drain feature 623B may be closer to the second gate electrodes 620 than the third side surface 614-S3 of the channel layer 614. Accordingly, when viewed from the top, the distance Dsd between the source/drain features 623A and 623B in direction D2 may be less than the length Lc of the channel layer 614. Additionally, more areas of the source/drain features 623 are in contact with the channel material.

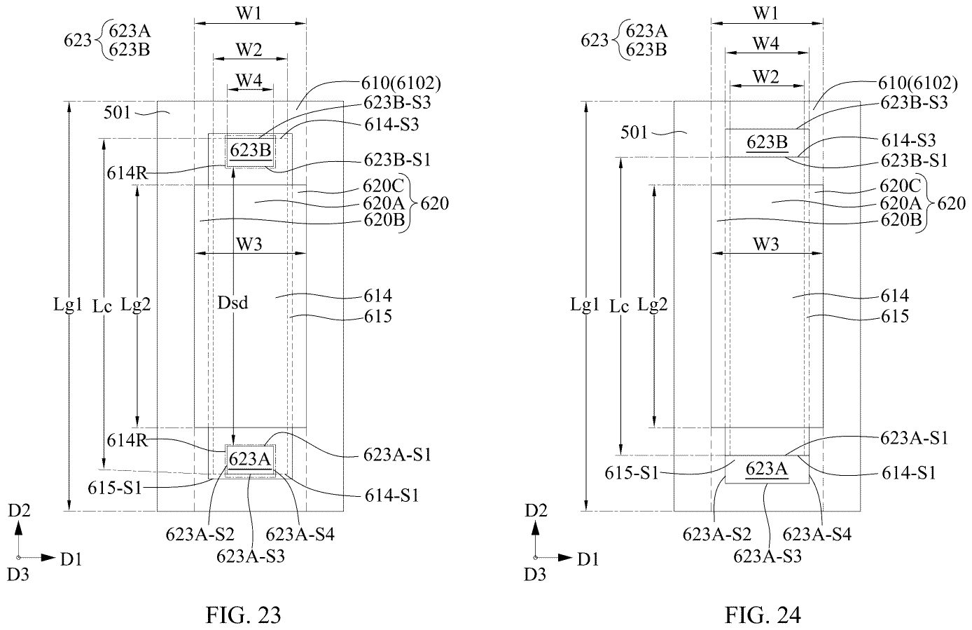

In some embodiments, as illustrated in FIG. 23, at least three lateral surfaces of the source/drain features 623 are in contact with the channel layer 614. Therefore, the contact area between the channel layer 614 and the source/drain features 623 can be increased, thereby improving the electrical connection therebetween.

In some embodiments, as illustrated in FIG. 23, the lateral surface 623A-S3 of the source/drain feature 623A is substantially aligned with the first side surface 614-S1 of the channel layer 614 when viewed from the top. Similarly, the lateral surface 623B-S3 of the source/drain feature 623B may be substantially aligned with the third side surface 614-S3 of the channel layer 614 when viewed from the top.

In some embodiments, as illustrated in FIG. 24, the width W4 of the source/drain features 623 is greater than the width W2 of the channel layer 614. The source/drain features 623 are in contact with the outermost sidewalls (e.g., the side surfaces 614-S1 and 614-S3) of the channel layer 614.

Although not intended to be limiting, one or more embodiments of the present disclosure provide many benefits to a semiconductor structure having memory structures and methods of forming the memory structures. According to the aforementioned description, several memory structures may be formed in BEOL of a semiconductor structure. In some embodiments, each of the memory structures may include a transistor (such as a TFT) and a memory cell formed on and coupled to the transistor (e.g., TFT). In some embodiments, the transistor includes a channel layer surrounded by a gate structure having two gate dielectric layers (e.g., high-k gate dielectric layers) and two gate electrodes, as illustrated above. The first gate electrode 610 (referred to as a bottom gate electrode) and the second gate electrode 620 (referred to as a top gate electrode) are positioned on opposite sides of a channel layer. The second gate electrode extends across three sides of the channel layer. In some embodiments, the channel layer is covered by two high-k gate dielectric layers (e.g., the first gate dielectric layer 613 and the second gate dielectric layer 615) and a combination of the first and second gate electrodes, thereby improving the gate control behavior and the electrical performances of the transistor. For example, the short-channel effects (SCEs) and the leakage current of the transistor can be reduced, especially when the transistor has shrunk gate length and channel length. In addition, the method of forming the transistor, in accordance with some embodiments, provides a simple way to form a GAA-like gate electrode structure without performing complex GAA-like processes.

In one exemplary aspect, the present disclosure is directed to a method of forming a semiconductor structure. The method includes forming a transistor having active regions in a substrate, and forming a memory structure over the substrate and above the transistor. The method of forming the memory structure includes forming a first gate electrode over the substrate and above the transistor, depositing a first gate dielectric layer on the first gate electrode, and depositing a channel layer on the first gate dielectric layer. The method of forming the memory structure further includes depositing a second gate dielectric layer on the first gate dielectric layer and covering the channel layer. The method of forming the memory structure further includes forming a second gate electrode on the second gate dielectric layer and around three sides of the channel layer. The method of forming the memory structure further includes forming source/drain features on the second gate dielectric layer and in lateral contact with opposite ends of the channel layer. The transistor is coupled to one of the source/drain features. The method of forming the memory structure further includes forming a memory cell on one of the source/drain features.

In another exemplary aspect, the present disclosure is directed to a method of forming a semiconductor structure. The method includes forming a memory structure over a substrate, and forming an interconnect structure over the memory structure. The method of forming the memory structure includes depositing a first gate electrode over the substrate, and forming a multilayered structure that includes a channel layer encapsulated by a first gate dielectric layer on the first gate electrode and a second gate dielectric layer on the first gate dielectric layer. The method of forming the memory structure further includes depositing a second gate electrode on the second gate dielectric layer and across multiple sides of the channel layer. The method o f forming the memory structure further includes forming source/drain contacts on the second gate dielectric layer, wherein the source/drain contacts are connected to opposite side surfaces of the channel layer. The method of forming the memory structure further includes forming a memory cell on one of the source/drain contacts.

In yet another exemplary aspect, the present disclosure is directed to a semiconductor structure, including a first gate electrode disposed over a substrate, a multilayered structure, a second gate electrode, source/drain features, a memory cell disposed on one of the source/drain features, and an interconnect structure disposed over the source/drain features and the memory cell. The multilayered structure includes a channel layer covered by a first gate dielectric layer disposed on the first gate electrode and a second gate dielectric layer disposed on the first gate dielectric layer. The second gate electrode is disposed on the second gate dielectric layer and across three sides of the channel layer. The source/drain features are disposed on the second gate dielectric layer and in contact with opposite side surfaces of the channel layer. The interconnect structure comprises a plurality of metal lines (e.g., 34L, 35L, 36L, 37L) disposed in the plurality of interconnect dielectric layers (e.g., 24, 25, 26, 27), and the memory cell is formed in one of the interconnect dielectric layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a transistor having active regions in a substrate; and
forming a memory structure over the substrate and above the transistor, comprising:
forming a first gate electrode over the substrate and above the transistor;
depositing a first gate dielectric layer on the first gate electrode;
depositing a channel layer on the first gate dielectric layer;
depositing a second gate dielectric layer on the first gate dielectric layer and covering the channel layer;
forming a second gate electrode on the second gate dielectric layer and around three sides of the channel layer;
forming source/drain features on the second gate dielectric layer and in lateral contact with opposite ends of the channel layer, wherein the transistor is coupled to one of the source/drain features; and
forming a memory cell on one of the source/drain features.

2. The method of claim 1, comprising:
depositing the channel layer having a lengthwise direction that is the same as a lengthwise direction of the first gate electrode.

3. The method of claim 1, comprising:
depositing the channel layer having a vertical projection on the first gate electrode, wherein an area of the vertical projection is positioned within the first gate electrode.

4. The method of claim 1, wherein the second gate electrode has an inverted U-shaped cross-section.

5. The method of claim 1, comprising:
forming the second gate electrode across the channel layer along a first direction; and
forming the source/drain features that are separated from each other in a second direction,
wherein the first direction is different from the second direction.

6. The method of claim 1, wherein after forming the second gate electrode, the method comprises:
forming source/drain trenches in an insulation that is disposed on the second gate dielectric layer and the second gate electrode,
wherein a portion of the second gate dielectric layer is removed, such that the source/drain trenches expose the opposite ends of the channel layer.

7. The method of claim 6, wherein after forming the source/drain trenches, a remaining portion of the second gate dielectric layer that is on the three sides of the channel layer has an inverted U-shaped cross-section.

8. The method of claim 1, further comprising:
forming a plurality of the memory structures; and
forming a common conductive line on a plurality of the second gate electrodes.

9. A method of forming a semiconductor structure, comprising:
forming a memory structure over a substrate, comprising:
depositing a first gate electrode over the substrate;
forming a multilayered structure that comprises a channel layer encapsulated by a first gate dielectric layer on the first gate electrode and a second gate dielectric layer on the first gate dielectric layer;
depositing a second gate electrode on the second gate dielectric layer and across multiple sides of the channel layer;
forming source/drain contacts on the second gate dielectric layer, wherein the source/drain contacts are connected to opposite side surfaces of the channel layer; and
forming a memory cell on one of the source/drain contacts; and
forming an interconnect structure over the source/drain contacts and the memory cell,
wherein the interconnect structure comprises a plurality of metal lines disposed in the plurality of interconnect dielectric layers, and the memory cell is formed in one of the interconnect dielectric layers.

10. The method of claim 9, comprising:
forming an insulating material layer over the substrate,
depositing the first gate electrode in the insulating material layer, wherein a top surface of the first gate electrode is leveled with a top surface of the insulating material layer; and
blanketly depositing the first gate dielectric layer on the insulating material layer and covering the first gate electrode and the insulating material layer.

11. The method of claim 9, wherein forming the source/drain contacts comprises:
removing portions of the second gate dielectric layer to expose the opposite ends of the channel layer,
wherein a remaining portion of the second gate dielectric layer is positioned on the multiple sides of the channel layer.

12. The method of claim 9, wherein forming the source/drain contacts comprises:
removing portions of the second gate dielectric layer and portions of the channel layer to form source/drain trenches, wherein a remaining portion of the channel layer has recessed regions at opposite ends in top view; and
filling a conductive material in the source/drain trenches to form the source/drain contacts each having a bottom surface in contact with a lower part of the second gate dielectric layer.

13. The method of claim 9, comprising:
forming the source/drain contacts at positions that are separated from each other along a lengthwise direction of the channel layer.

14. The method of claim 9, comprising:
forming the source/drain contacts each having a bottom surface coplanar with a lowermost surface of the second gate electrode.

15. A semiconductor structure, comprising:
a first gate electrode disposed over a substrate;
a multilayered structure, comprising a channel layer covered by a first gate dielectric layer disposed on the first gate electrode and a second gate dielectric layer disposed on the first gate dielectric layer;
a second gate electrode disposed on the second gate dielectric layer and across three sides of the channel layer;
source/drain features disposed on the second gate dielectric layer and in contact with opposite side surfaces of the channel layer;
a memory cell disposed on one of the source/drain features; and
an interconnect structure disposed over the source/drain features and the memory cell,
wherein the interconnect structure comprises a plurality of metal lines disposed in the plurality of interconnect dielectric layers, and the memory cell is formed in one of the interconnect dielectric layers.

16. The semiconductor structure of claim 15, wherein the second gate electrode and the first gate dielectric layer are separated by the second gate dielectric layer.

17. The semiconductor structure of claim 15, wherein a lowermost surface of the second gate electrode is in contact with the second gate dielectric layer.

18. The semiconductor structure of claim 15, wherein the second gate electrode has an inverted U-shaped cross-section.

19. The semiconductor structure of claim 15, wherein a bottom surface of the channel layer is lower than bottom surfaces of the source/drain features.

20. The semiconductor structure of claim 15, wherein the second gate electrode is positioned across the channel layer in a first direction, and the source/drain features are separated from each other in a second direction,
wherein the channel layer has a length in the second direction greater than a length of the second gate electrode in the second direction, and less than a length of the first gate electrode in the second direction.
